(19) United States
(12) Patent Application Publication
(10) Pub. No.: US 2025/0256406 A1
(43) Pub. Date: Aug. 14, 2025

(54) SUBSTRATE PROCESSING APPARATUS

(71) Applicant: SCREEN Holdings Co., Ltd., Kyoto (JP)

(72) Inventors: Ichiro MITSUYOSHI, Kyoto (JP); Hidehiko OZAKI, Kyoto (JP); Tadashi MAEGAWA, Kyoto (JP); Nozomu NAKAGAWA, Kyoto (JP)

(21) Appl. No.: 19/047,026

(22) Filed: Feb. 6, 2025

(30) Foreign Application Priority Data
Feb. 8, 2024 (JP) 2024-018104

(51) Int. Cl. B25J 11/00; H01L 21/677; H01L 21/68

(52) U.S. Cl. CPC B25J 11/0095; H01L 21/67718; H01L 21/68

(57) ABSTRACT

An orientation changing unit of a substrate processing apparatus includes a vertical holding unit having reference pitch holding grooves and ⅔ pitch holding grooves, and a holding groove switching drive unit. The reference pitch holding grooves are disposed at a reference pitch. The ⅔ pitch holding groove are disposed at a ⅔ pitch that is ⅔ times the reference pitch. The holding groove switching drive unit switches to a state in which the reference pitch holding grooves are usable when 50 substrates aligned in a face-to-back manner are formed on a pusher member, and switches to a state in which the ⅔ pitch holding grooves are usable when the 50 substrates held by the pusher member is rearranged into a face-to-face manner.

### CROSS-REFERENCE TO RELATED APPLICATIONS

This application claims priority to Japanese Patent Application No. 2024-018104 filed Feb. 8, 2024, the subject matter of which is incorporated herein by reference in entirety.

### BACKGROUND

### Technical Field

The present invention relates to a substrate processing apparatus that processes a substrate. Examples of the substrate include a semiconductor substrate, a substrate for a flat panel display (FPD), a glass substrate for a photomask, a substrate for an optical disk, a substrate for a magneto-optical disk, a ceramic substrate, and substrate for a solar cell. Examples of the FPD include a liquid crystal display device and an organic electroluminescence (EL) display device.

### Related Art

Conventionally, a substrate processing apparatus that collectively immerses and processes a plurality of substrates in a processing liquid is known. The substrate processing apparatus includes an orientation changing mechanism (orientation changing unit) and a pusher (pusher mechanism) (see, for example, JP 2010-093230 A). The orientation changing mechanism changes the orientation of the substrate between a horizontal orientation and a vertical orientation. The pusher can deliver and receive a plurality of substrates in a vertical orientation to and from the orientation changing mechanism with an up-down movement of a lifting and holding unit (pusher member).

After 25 substrates are delivered from the orientation changing mechanism to the lifting and holding unit, the lifting and holding unit turns 180 degrees about a vertical axis. With the turning of 180 degrees, the held 25 substrates move by a half pitch. In this state, another 25 substrates are delivered from the orientation changing mechanism to the lifting and holding unit. As a result, the 25 substrates delivered later enter between the 25 substrates delivered earlier, and a substrate group of a total of 50 substrates is formed on the lifting and holding unit. At this time, two adjacent substrates are in a face-to-face state in which their front surfaces (or the back surfaces) face each other. The 50 substrates held by the lifting and holding unit are aligned at a half pitch that is half the substrate holding pitch in a carrier.

### SUMMARY

To reduce the amount of processing liquid (chemical liquid and cleaning liquid) used in the substrate processing apparatus, there is a demand for aligning a plurality of substrates at a pitch narrower than the half pitch and collectively processing the plurality of substrates aligned at the narrow pitch. In this case, it may be difficult to bring the plurality of substrates aligned at a narrow pitch narrower than the half pitch into a face-to-face state.

The present invention has been made in view of such circumstances, and an object thereof is to provide a substrate processing apparatus capable of easily aligning a plurality of substrates at a narrow pitch narrower than a half pitch in a face-to-face manner.

To achieve such an object, the present invention has the following configurations. That is, a substrate processing apparatus according to the present invention is a substrate processing apparatus that collectively processes a plurality of substrates, the substrate processing apparatus including a substrate handling mechanism including a plurality of hands disposed in a vertical direction at a reference pitch, each of which holds one substrate in a horizontal orientation, an orientation changing unit that individually changes an orientation of N substrate groups each including two or more substrates aligned at the reference pitch from the horizontal orientation to a vertical orientation, wherein N is a natural number of three or more, the N substrate groups being sequentially received from the substrate handling mechanism, and a pusher mechanism including a pusher member that holds the plurality of substrates aligned in the vertical orientation at a 1/N pitch that is 1/N times the reference pitch, the pusher mechanism forming the plurality of substrates on the pusher member by aligning the N substrate groups received from the orientation changing unit in one row with the pusher member while shifting the pusher member by the 1/N pitch in an alignment direction in which the plurality of substrates are aligned, wherein the orientation changing unit includes a support base, a pair of horizontal holding units that holds one substrate group of the N substrate groups in the horizontal orientation, the pair of horizontal holding units being provided in such a manner as to extend at a right angle with respect to a support surface of the support base, a pair of vertical holding units including a plurality of pairs of reference pitch holding grooves and a plurality of pairs of 2/N pitch holding grooves, the pair of vertical holding units being provided in such a manner as to extend at the right angle with respect to the support surface of the support base, a rotation drive unit that rotates the support base about a horizontal axis, and a switching drive unit that switches between a state in which the plurality of pairs of reference pitch holding grooves are usable and a state in which the plurality of pairs of 2/N pitch holding grooves are usable, the plurality of pairs of reference pitch holding grooves are disposed at the reference pitch in an extending direction in which the pair of vertical holding units extends, the plurality of pairs of 2/N pitch holding grooves are disposed at a 2/N pitch that is 2/N times the reference pitch in the extending direction, and the switching drive unit switches to the state in which the plurality of pairs of reference pitch holding grooves are usable when the plurality of substrates aligned in a face-to-back manner are formed in the pusher member, and switches to the state in which the plurality of pairs of 2/N pitch holding grooves are usable when the plurality of substrates held by the pusher member are rearranged into a face-to-face manner.

According to the substrate processing apparatus of the present invention, the pair of vertical holding units of the orientation changing unit includes a plurality of pairs of reference pitch holding grooves and a plurality of pairs of 2/N pitch holding grooves. The plurality of pairs of reference pitch holding grooves are disposed at a reference pitch. The plurality of pairs of 2/N pitch holding grooves are disposed at a 2/N pitch that is 2/N times the reference pitch. The switching drive unit switches to a state in which the plurality of pairs of reference pitch holding grooves are usable. With this operation, the pusher mechanism can cause the pusher member to hold the plurality of substrate groups each aligned at the reference pitch while moving them by the 1/N pitch. Thus, a plurality of substrates aligned at the 1/N pitch in a face-to-back manner are once held by the pusher member.

The switching drive unit of the orientation changing unit switches to a state in which the plurality of pairs of 2/N pitch holding grooves are usable. As a result, the orientation changing unit can extract two or more first substrates out of the plurality of substrates in which two or more first substrates and two or more second substrates are alternately disposed from the plurality of substrates held by the pusher member. Thereafter, the pusher mechanism rotates the two or more second substrates remaining on the pusher member by 180 degrees about a vertical axis. Thereafter, the two or more first substrates extracted by the orientation changing unit are returned to the pusher member. With this operation, a plurality of substrates aligned at the 1/N pitch in a face-to-face manner are held by the pusher member. Thus, a plurality of substrates can be easily aligned at the 1/N pitch narrower than a half pitch in a face-to-face manner.

In the substrate processing apparatus described above, it is preferable that a first vertical holding unit of the pair of vertical holding unit is rotatable about a first rotation axis passing through the first vertical holding unit and extending at a right angle with respect to the support surface, the first vertical holding unit includes a first outer peripheral surface and a second outer peripheral surface provided around the first rotation axis, a second vertical holding unit of the pair of vertical holding unit is rotatable about a second rotation axis passing through the second vertical holding unit and extending at a right angle with respect to the support surface, the second vertical holding unit includes a third outer peripheral surface and a fourth outer peripheral surface provided around the second rotation axis, the first outer peripheral surface and the third outer peripheral surface are provided with the plurality of pairs of reference pitch holding grooves, the second outer peripheral surface and the fourth outer peripheral surface are provided with the plurality of pairs of 2/N pitch holding grooves, and the switching drive unit rotates the first vertical holding unit about the first rotation axis and rotates the second vertical holding unit about the second rotation axis to switch between the state in which the plurality of pairs of reference pitch holding grooves are usable and the state in which the plurality of pairs of 2/N pitch holding grooves are usable.

The switching drive unit rotates the first vertical holding unit about the first rotation axis and rotates the second vertical holding unit about the second rotation axis. This allows the switching drive unit to switch between a state in which the plurality of pairs of reference pitch holding grooves are usable and a state in which the plurality of pairs of 2/N pitch holding grooves are usable.

In the substrate processing apparatus described above, it is preferable that the first vertical holding unit includes a fifth outer peripheral surface and a sixth outer peripheral surface provided around the first rotation axis in addition to the first outer peripheral surface and the second outer peripheral surface, the second vertical holding unit includes a seventh outer peripheral surface and an eighth outer peripheral surface provided around the second rotation axis in addition to the third outer peripheral surface and the fourth outer peripheral surface, the fifth outer peripheral surface and the seventh outer peripheral surface are provided with a plurality of pairs of post-processing reference pitch holding grooves disposed at the reference pitch in the extending direction, the sixth outer peripheral surface and the eighth outer peripheral surface are provided with a plurality of pairs of post-processing 2/N pitch holding grooves disposed at the 2/N pitch in the extending direction, the switching drive unit rotates the first vertical holding unit about the first rotation axis and rotates the second vertical holding unit about the second rotation axis to switch between the state in which the plurality of pairs of reference pitch holding grooves are usable, the state in which the plurality of pairs of 2/N pitch holding grooves are usable, a state in which the plurality of pairs of post-processing reference pitch holding grooves are usable, and a state in which the plurality of pairs of post-processing 2/N pitch holding grooves are usable, and the switching drive unit switches to the state in which the plurality of pairs of post-processing 2/N pitch holding grooves are usable when the plurality of substrates held by the pusher member are rearranged into a face-to-back manner, and switches to the state in which the plurality of pairs of post-processing reference pitch holding grooves are usable when the plurality of substrates held by the pusher member are divided into the N substrate groups.

The switching drive unit rotates the first vertical holding unit about the first rotation axis and rotates the second vertical holding unit about the second rotation axis. With this operation, the switching drive unit can switch between four states, that is, between a state in which the plurality of pairs of reference pitch holding grooves are usable, a state in which the plurality of pairs of 2/N pitch holding grooves are usable, a state in which the plurality of pairs of post-processing reference pitch holding grooves are usable, and a state in which the plurality of pairs of post-processing 2/N pitch holding grooves are usable.

It is preferable that the substrate processing apparatus described above includes a controller, wherein the controller causes the switching drive unit to switch to the state in which the plurality of pairs of reference pitch holding grooves are usable, causes the orientation changing unit to sequentially receive the N substrate groups from the substrate handling mechanism, causes the orientation changing unit to individually change the orientation of the N substrate groups from a horizontal orientation to a vertical orientation, causes the pusher mechanism to hold the plurality of substrates aligned at the 1/N pitch in a face-to-back manner with the pusher member, the plurality of substrates being formed from the N substrate groups by the pusher member sequentially receiving the N substrate groups while the pusher member is shifted in the alignment direction by the 1/N pitch, causes the switching drive unit to switch to the state in which the plurality of pairs of 2/N pitch holding grooves are usable, causes the pair of vertical holding units to receive, from the pusher member, two or more first substrates aligned at the 2/N pitch among the plurality of substrates in which the two or more first substrates and two or more second substrates are alternately disposed, causes the pusher mechanism to rotate the pusher member holding the two or more second substrates in a vertical orientation by 180 degrees about a vertical axis, and causes the pusher member to receive the two or more first substrates from the pair of vertical holding units while alternately disposing the two or more first substrates and the two or more second substrates rotated by 180 degrees.

It is preferable that the substrate processing apparatus described above further includes a substrate processing unit that collectively processes the plurality of substrates aligned at the 1/N pitch in a face-to-face manner, and a main conveyance mechanism that conveys the plurality of substrates aligned at the 1/N pitch in a face-to-face manner to the substrate processing unit.

The plurality of substrates to be collectively processed are aligned at a pitch narrower than the half pitch. Thus, the size of the substrate processing unit for accommodating the plurality of substrates can be reduced. For example, when the substrate processing unit is a batch processing tank, the use amount of the processing liquid (chemical liquid and cleaning liquid) can be reduced.

In the substrate processing apparatus described above, for example, the N substrate groups are three substrate groups, the 1/N pitch is a ⅓ pitch that is ⅓ times the reference pitch, and the plurality of pairs of 2/N pitch holding grooves are a plurality of pairs of ⅔ pitch holding grooves disposed at a ⅔ pitch that is ⅔ times the reference pitch in the extending direction.

In the substrate processing apparatus described above, for example, the N substrate groups are three substrate groups, the 1/N pitch is a ⅓ pitch that is ⅓ times the reference pitch, the plurality of pairs of 2/N pitch holding grooves are a plurality of pairs of ⅔ pitch holding grooves disposed at a ⅔ pitch that is ⅔ times the reference pitch in the extending direction, and the plurality of pairs of post-processing 2/N pitch holding grooves are a plurality of pairs of post-processing ⅔ pitch holding grooves disposed at the ⅔ pitch in the extending direction.

The substrate processing apparatus according to the present invention can easily align a plurality of substrates at a pitch narrower than a half pitch in a face-to-face manner.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a plan view illustrating a schematic configuration of a substrate processing apparatus according to a first embodiment;

FIG. 2 is a side view of a substrate handling mechanism;

FIG. 3 is a side view of an orientation changing unit;

FIG. 4 is a plan view illustrating the orientation changing unit in a state where a pair of vertical holding units is separated from a pair of horizontal holding units;

FIG. 5 is a plan view illustrating the orientation changing unit in a state where the pair of vertical holding units has approached the pair of horizontal holding units;

FIG. 6 is a plan view mainly illustrating the pair of vertical holding units in a horizontal orientation in a first state in which a plurality of pairs of reference pitch holding grooves are usable when viewed as indicated by the arrows A-A in FIGS. 4 and 5;

FIG. 7 is a plan view mainly illustrating the pair of vertical holding units in a horizontal orientation in a second state in which a plurality of pairs of ⅔ pitch holding grooves are usable when viewed as indicated by the arrows A-A in FIGS. 4 and 5;

FIG. 8 is a side view of a pusher mechanism;

FIG. 9 is a longitudinal sectional view illustrating a pusher member that holds a plurality of substrates aligned at ⅓ pitch in a face-to-face manner in a vertical orientation;

FIG. 10 is a flowchart for describing a first half operation of the substrate processing apparatus;

FIG. 11 is a flowchart for describing a later half operation of the substrate processing apparatus;

FIGS. 12A and 12B are diagrams for describing an operation of the substrate processing apparatus;

FIGS. 13A and 13B are diagrams for describing an operation of the substrate processing apparatus;

FIGS. 14A and 14B are diagrams for describing an operation of the substrate processing apparatus;

FIGS. 15A and 15B are diagrams for describing an operation of the substrate processing apparatus;

FIGS. 16A and 16B are diagrams for describing an operation of the substrate processing apparatus;

FIGS. 17A and 17B are diagrams for describing an operation of the substrate processing apparatus;

FIGS. 18A and 18B are diagrams for describing an operation of the substrate processing apparatus;

FIGS. 19A and 19B are diagrams for describing an operation of the substrate processing apparatus;

FIGS. 20A and 20B are diagrams for describing an operation of the substrate processing apparatus;

FIGS. 21A and 21B are diagrams for describing an operation of the substrate processing apparatus;

FIGS. 22A and 22B are diagrams for describing an operation of the substrate processing apparatus;

FIG. 23 is a plan view illustrating an orientation changing unit according to a second embodiment; and

FIGS. 24A and 24B are side views illustrating an orientation changing unit according to a modification.

### DETAILED DESCRIPTION

Hereinafter, various embodiments of the present invention will be described.

### First Embodiment

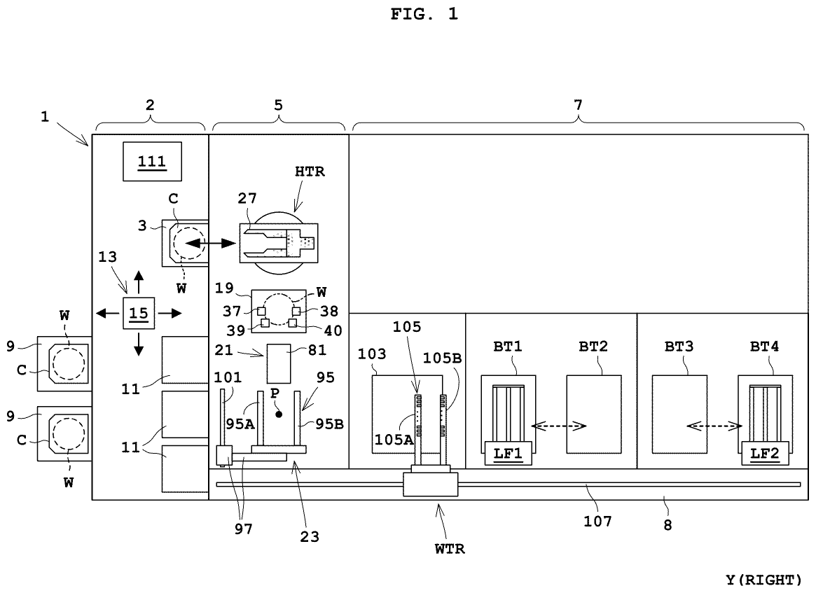

Hereinafter, a first embodiment of the present invention will be described with reference to the drawings. FIG. 1 is a plan view illustrating a schematic configuration of a substrate processing apparatus 1 according to the first embodiment.

In the present specification, for convenience, the directions in which a transfer block 5 and a processing block 7 are arranged are referred to as “front-back directions X”. The front-back directions X are horizontal. Of the front-back directions X, for example, the direction from the processing block 7 toward the transfer block 5 is referred to as “front direction”. The direction opposite to the front direction is referred to as “back direction”. The horizontal directions orthogonal to the front-back directions X are referred to as “width directions Y”. One direction in the “width directions Y” is appropriately referred to as “right direction”. The direction opposite to the right direction is referred to as “left direction”. The directions perpendicular to the horizontal directions are referred to as “vertical directions Z”. In each drawing, front, back, right, left, top, and bottom are appropriately shown for reference.

### <1. Configuration of Substrate Processing Apparatus>

See FIG. 1. The substrate processing apparatus 1 processes a substrate W. The substrate processing apparatus 1 is a batch-type substrate processing apparatus that collectively processes a plurality of (for example, 50, 75, or 100) substrates W. In the present embodiment, a case where 50 substrates W are collectively processed will be described. Substrates W1, W2, W3, W11, W12, and the like are referred to as substrates W unless otherwise distinguished.

The substrate processing apparatus 1 performs, for example, chemical liquid processing, cleaning processing, drying processing, and the like on the substrate W. The substrate processing apparatus 1 includes a stocker 2, a placement shelf 3, a transfer block 5, a processing block 7, and a batch substrate conveyance region 8.

### <1-1. Stocker>

The stocker 2 accommodates at least one carrier C. The stocker 2 is adjacent to the front of the transfer block 5. The carrier C stores a plurality of (for example, 25) substrates W at a predetermined interval (for example, 10 mm) in a horizontal orientation. In other words, the carrier C stores a plurality of substrates W in a horizontal orientation aligned in the vertical directions Z and at a reference pitch (for example, 10 mm pitch). The plurality of substrates W in the carrier C are aligned in the thickness directions of each substrate W. As the carrier C, for example, a front opening unified pod (FOUP) is used, but the carrier C is not limited to this.

The stocker 2 includes a plurality of (for example, two) load ports 9. The two load ports 9 are disposed in the width directions Y. In the present embodiment, the two load ports 9 are used for loading and unloading the carrier C. The stocker 2 includes at least one storage shelf 11 and a carrier conveyance robot 13. The carrier C is placed on the storage shelf 11.

The carrier conveyance robot 13 conveys the carrier C between the two load ports 9, the storage shelf 11, and the placement shelf 3. The carrier conveyance robot 13 includes, for example, a gripping unit 15 (gripper) that grips a protrusion provided on the upper surface of the carrier C. The carrier conveyance robot 13 can move the gripping unit 15 in horizontal directions (the front-back directions X and the width directions Y) and the vertical directions Z. The carrier conveyance robot 13 is driven by one or more electric motors.

The placement shelf 3 is disposed in a region of the stocker 2. The placement shelf 3 is adjacent to the front of the transfer block 5. The carrier C is placed on the placement shelf 3.

### <1-2. Transfer Block>

See FIG. 1. The transfer block 5 includes a substrate handling mechanism (robot) HTR, an orientation changing unit 19, a pusher mechanism 21, and a delivery mechanism 23.

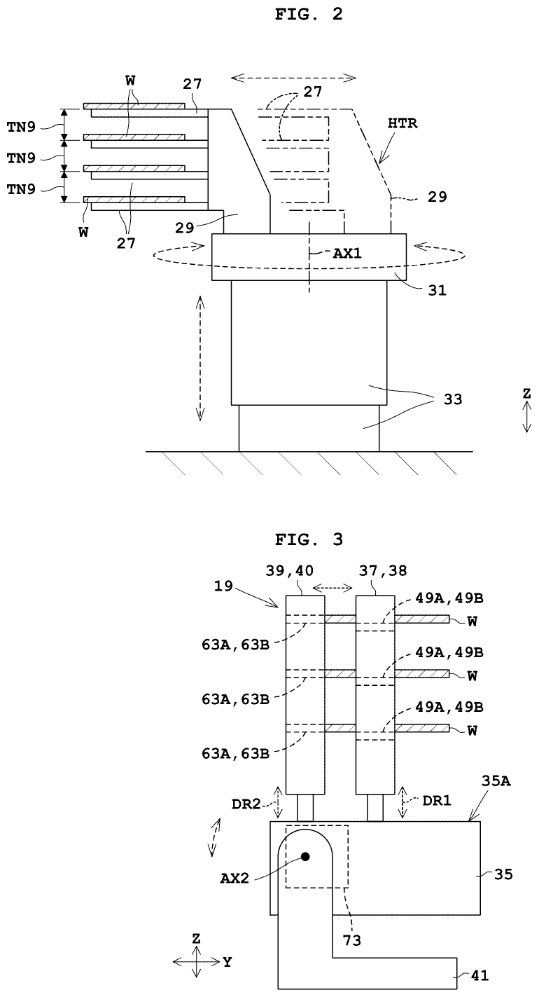

The substrate handling mechanism HTR is disposed behind the placement shelf 3. The substrate handling mechanism HTR conveys a plurality of (for example, 17 or 16) substrates W in a horizontal orientation between the carrier C placed on the placement shelf 3 and the orientation changing unit 19. As illustrated in FIG. 2, the substrate handling mechanism HTR includes a plurality of (for example, 25 or 17) hands 27. Each hand 27 holds one substrate W in a horizontal orientation. The plurality of hands 27 is disposed in the vertical directions Z at a reference pitch (for example, 10 mm pitch). Thus, for example, the 25 substrates W held by the 25 hands 27 are aligned at the reference pitch. The reference pitch repeats a reference interval TN9 (for example, 10 mm).

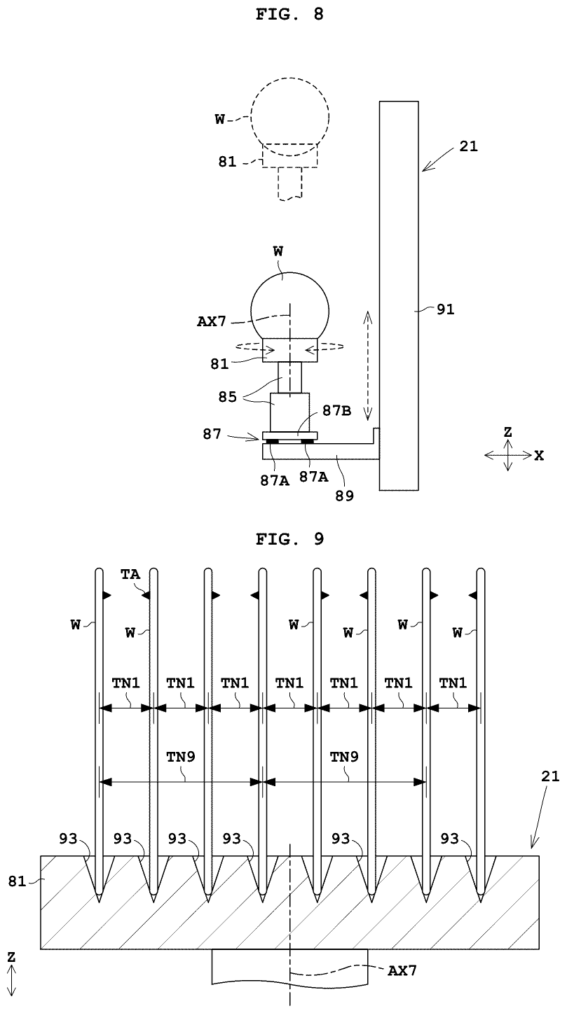

In FIG. 2 and the like, for convenience of illustration, the substrate handling mechanism HTR includes four hands 27. A pair of horizontal holding unit 37 and 38 and a pair of vertical holding units 39 and 40 described later hold three substrates W. A pusher member 81 (see FIG. 9) to be described later supports eight substrates W.

The substrate handling mechanism HTR further includes a hand support 29, a reciprocating unit 31, and a lifting and rotating unit 33. The hand support 29 supports the plurality of hands 27. The reciprocating unit 31 moves the plurality of hands 27 forward and backward via the hand support 29. The lifting and rotating unit 33 rotates the reciprocating unit 31 about a vertical axis AX1 to change the direction of the hands 27. The lifting and rotating unit 33 is fixed to a floor surface. The reciprocating unit 31 and the lifting and rotating unit 33 each include an electric motor. The substrate handling mechanism HTR may include a movable hand (not illustrated) for conveying only one substrate W, separately from the hands 27.

The orientation changing unit 19 changes the orientation of a plurality of (for example, 17 or 16) substrates W between a horizontal orientation and a vertical orientation. Specifically, the orientation changing unit 19 individually changes the orientation of three substrate groups (first substrate group, second substrate group, and third substrate group) sequentially received from the substrate handling mechanism HTR from a horizontal orientation to a vertical orientation. Each of the three substrate groups includes two or more (for example, 17 or 16) substrates W aligned at a reference pitch (for example, 10 mm pitch).

The orientation changing unit 19 is disposed on the left side of the substrate handling mechanism HTR. As illustrated in FIGS. 3 to 5, the orientation changing unit 19 includes a support base 35, a pair of horizontal holding units 37 and 38, a pair of vertical holding units 39 and 40, and a rotation drive unit 41.

The support base 35 is rotatably supported about a horizontal axis AX2 extending in the front-back directions X. Each of the pair of horizontal holding units 37 and 38 and the pair of vertical holding units 39 and 40 is provided so as to extend at a right angle with respect to a support surface 35A. The pair of horizontal holding units 37 and 38 holds, for example, 17 or 16 substrates W of one substrate group in a horizontal orientation. That is, the pair of horizontal holding units 37 and 38 holds the peripheral edge portions of, for example, 17 or 16 substrates W in a horizontal orientation. The pair of vertical holding units 39 and 40 holds, for example, 17 or 16 substrates W of one substrate group in a vertical orientation.

The rotation drive unit 41 rotates the support base 35 about the horizontal axis AX2. This can change the orientation of the plurality of substrates W held by the pair of horizontal holding units 37 and 38 and the pair of vertical holding units 39 and 40 between a horizontal orientation and a vertical orientation. The rotation drive unit 41 includes, for example, an electric motor.

Next, details of the pair of horizontal holding units 37 and 38 will be described. The pair of horizontal holding units 37 and 38 is disposed in the front-back directions X. A first horizontal holding unit 37 is rotatable about a rotation axis AX3 passing through the first horizontal holding unit 37 and extending at a right angle with respect to the support surface 35A. The first horizontal holding units 37 includes a first surface 43A, a second surface 45A, and a first retraction surface 47A provided around the rotation axis AX3. The first surface 43A is provided on the opposite side of the second surface 45A.

A second horizontal holding unit 38 is rotatable about a rotation axis AX4 passing through the second horizontal holding unit 38 and extending at a right angle with respect to the support surface 35A. The second horizontal holding units 38 includes a third surface 43B, a fourth surface 45B, and a second retraction surface 47B provided around the rotation axis AX4. The third surface 43B is provided on the opposite side of the fourth surface 45B.

The pair of horizontal holding units 37 and 38 includes a plurality of pairs (for example, 17 pairs) of pre-processing shelves 49A and 49B and a plurality of pairs (for example, 17 pairs) of post-processing shelves 51A and 51B. The plurality of pairs of pre-processing shelves 49A and 49B and the plurality of pairs of post-processing shelves 51A and 51B are both disposed at a reference pitch (for example, 10 mm pitch) in a direction DR1 (see FIG. 3) in which the pair of horizontal holding units 37 and 38 (each of the horizontal holding units 37 and 38) extends.

The plurality of pairs of pre-processing shelves 49A and 49B are provided on the first surface 43A and the third surface 43B. On the other hand, the plurality of pairs of post-processing shelves 51A and 51B are provided on the second surface 45A and the fourth surface 45B. A shelf such as the shelf 49A is not provided on the first retraction surface 47A or the second retraction surface 47B. When the first retraction surface 47A and the second retraction surface 47B face each other (that is, in a state where the first retraction surface 47A and the second retraction surface 47B are usable), a width WD1 between the first retraction surface 47A and the second retraction surface 47B is larger than the diameter of the substrate W (see FIG. 5).

The orientation changing unit 19 further includes a shelf switching drive unit 53. The shelf switching drive unit 53 includes at least one electric motor. The shelf switching drive unit 53 rotates the first horizontal holding unit 37 about the rotation axis AX3 and rotates the second horizontal holding unit 38 about the rotation axis AX4. This can switch between a state in which the plurality of pairs of pre-processing shelves 49A and 49B are usable, a state in which the plurality of pairs of post-processing shelves 51A and 51B are usable, and a state in which the first retraction surface 47A and the second retraction surface 47B are usable. That is, the shelf switching drive unit 53 can switch three states.

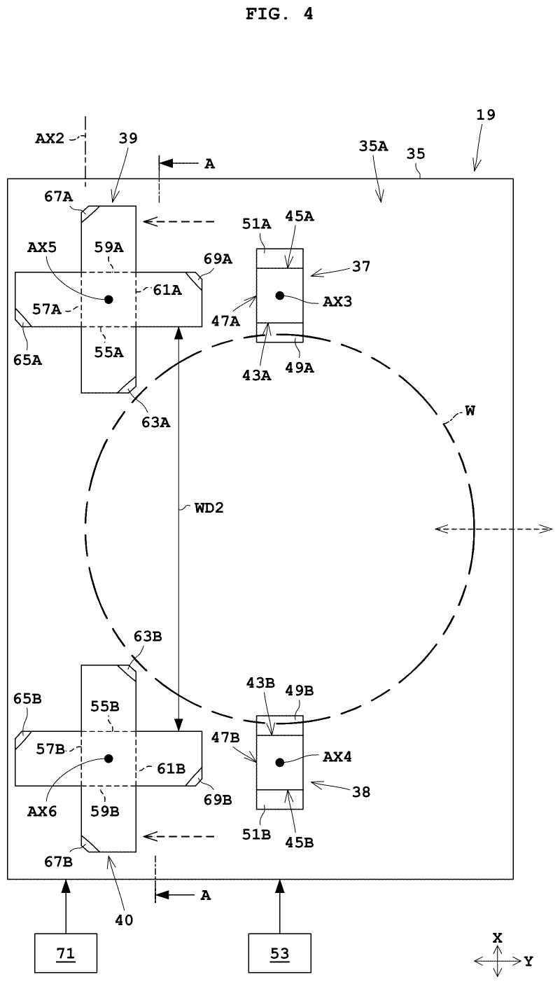

When the plurality of pairs of pre-processing shelves 49A and 49B are in a usable state, the plurality of pairs of pre-processing shelves 49A and 49B face each other (see FIG. 4). When the plurality of pairs of post-processing shelves 51A and 51B are in a usable state, the plurality of pairs of post-processing shelves 51A and 51B face each other.

For example, when receiving a plurality of substrates before processing from the substrate handling mechanism HTR, the shelf switching drive unit 53 switches to the state in which the plurality of pairs of pre-processing shelves 49A and 49B are usable. When individually holding three substrate groups of the plurality of substrates W after processing in a horizontal orientation, the shelf switching drive unit 53 switches to the state in which the plurality of pairs of post-processing shelves 51A and 51B are usable. When delivering a plurality of substrates W between the pair of vertical holding units 39 and 40 (orientation changing unit 19) and the pusher member 81 (pusher mechanism 21), the shelf switching drive unit 53 switches to the state in which the first retraction surface 47A and the second retraction surface 47B are usable. This can prevent the pair of horizontal holding units 37 and 38 from being rubbed against the plurality of substrates W.

The orientation changing unit 19 may include a drive unit that brings the pair of horizontal holding units 37 and 38 close to the support surface 35A and separates the pair of horizontal holding units 37 and 38 from the support surface 35A along the rotation axes AX3 and AX4. The drive unit includes, for example, an electric actuator or an air cylinder.

Next, details of the pair of vertical holding units 39 and 40 will be described. The pair of vertical holding units 39 and 40 is disposed in the front-back directions X. The first vertical holding unit 39 is rotatable about a rotation axis AX5 passing through the first vertical holding unit 39 and extending at a right angle with respect to the support surface 35A. The first vertical holding unit 39 includes four outer peripheral surfaces 55A, 57A, 59A, and 61A provided around the rotation axis AX5. The outer peripheral surface 55A is provided on the opposite side of the outer peripheral surface 59A. The outer peripheral surface 57A is provided on the opposite side of the outer peripheral surface 61A. The arrangement of the four outer peripheral surfaces 55A, 57A, 59A, and 61A is not particularly limited.

The second vertical holding unit 40 is rotatable about a rotation axis AX6 passing through the second vertical holding unit 40 and extending at a right angle with respect to the support surface 35A. The second vertical holding unit 40 includes four outer peripheral surfaces 55B, 57B, 59B, and 61B provided around the rotation axis AX6. The outer peripheral surface 55B is provided on the opposite side of the outer peripheral surface 59B. The outer peripheral surface 57B is provided on the opposite side of the outer peripheral surface 61B. The arrangement of the four outer peripheral surfaces 55B, 57B, 59B, and 61B is not particularly limited.

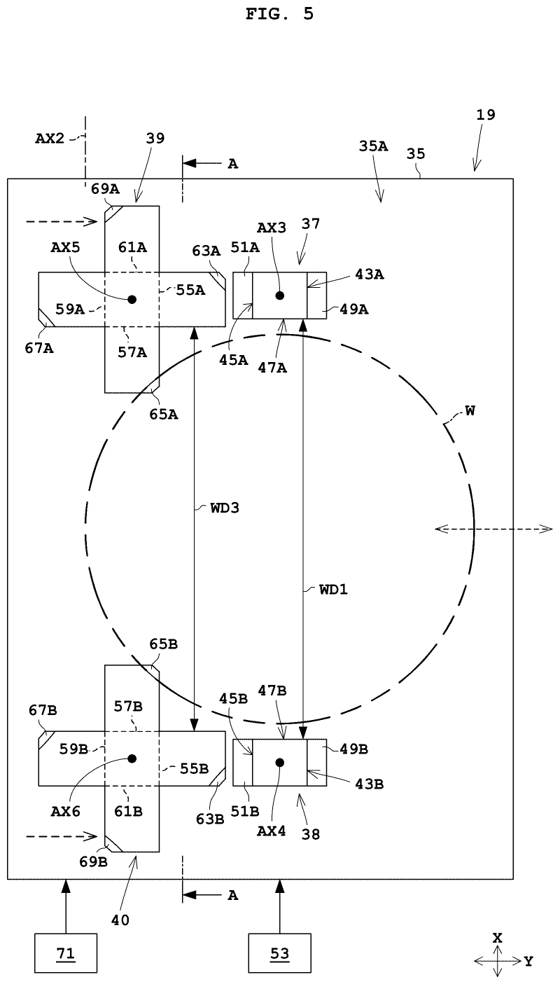

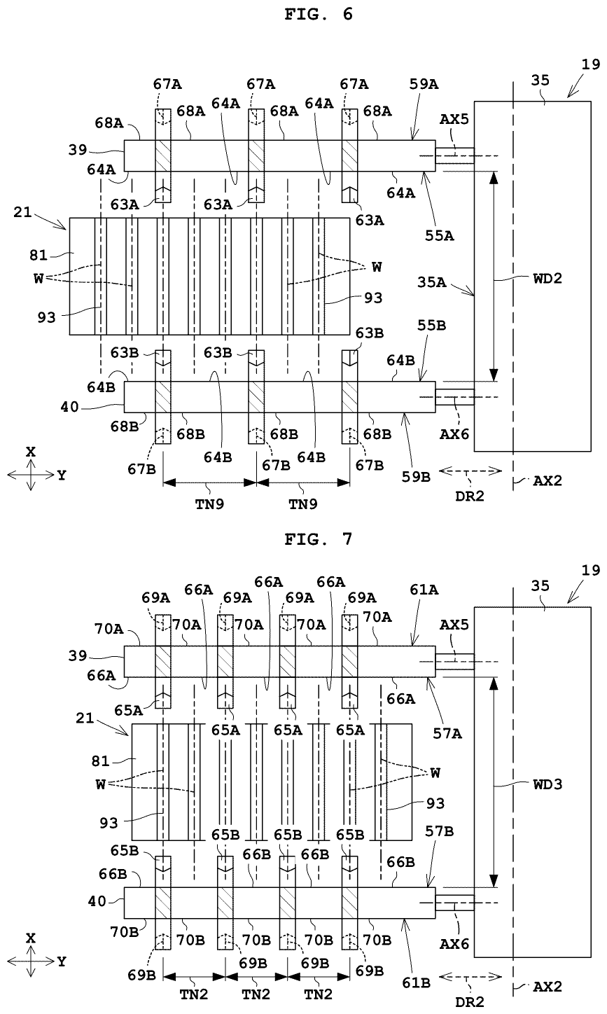

FIGS. 6 and 7 are plan views mainly illustrating the pair of vertical holding units 39 and 40 in a horizontal orientation when viewed as indicated by the arrows A-A in FIGS. 4 and 5. The pair of vertical holding units 39 and 40 includes a plurality of pairs (for example, 17 pairs) of reference pitch holding grooves 63A and 63B and a plurality of pairs (for example, 25 pairs) of ⅔ pitch holding grooves 65A and 65B to handle the substrates W before processing.

As illustrated in FIG. 6, the plurality of pairs of reference pitch holding grooves 63A and 63B are disposed at a reference pitch (for example, 10 mm pitch) in the extending directions DR2 in which the pair of vertical holding units 39 and 40 (the vertical holding units 39 and 40) extends. On the other hand, as illustrated in FIG. 7, the plurality of pairs of ⅔ pitch holding grooves 65A and 65B are disposed at a ⅔ pitch (for example, 6.666 mm pitch) that is ⅔ times the reference pitch in the extending directions DR2. The ⅔ pitch repeats a second interval TN2 (for example, 6.666 mm) that is twice the first interval TN1 (for example, 3.333 mm).

A plurality of pairs (for example, 17 pairs) of reference pitch holding grooves 63A and 63B are provided on the two outer peripheral surfaces 55A and 55B. A plurality of pairs (for example, 25 pairs) of ⅔ pitch holding grooves 65A and 65B are provided on the two outer peripheral surfaces 57A and 57B.

The pair of vertical holding units 39 and 40 further includes a plurality of pairs (for example, 17 pairs) of reference pitch holding grooves 67A and 67B and a plurality of pairs (for example, 25 pairs) of ⅔ pitch holding grooves 69A and 69B to handle the substrates W after processing. The two outer peripheral surfaces 59A and 59B are provided with the plurality of pairs of reference pitch holding grooves 67A and 67B disposed at a reference pitch in the extending directions DR2. The two outer peripheral surfaces 61A and 61B are provided with the plurality of pairs of ⅔ pitch holding grooves 69A and 69B disposed at a ⅔ pitch (for example, 6.666 mm pitch) in the extending directions DR2.

The reference pitch holding grooves 67A and 67B are used to hold, for example, one substrate group (for example, 17 or 16 substrates W) that have been processed in a chemical liquid processing tank BT1 (described later). The ⅔ pitch holding grooves 69A and 69B are used to hold two or more (25) first substrates W11 (second substrates W12) among a plurality of (for example, 50) substrates W (W11 and W12) in which two or more (for example, 25) first substrates W11 and two or more (for example, 25) second substrates W12 that have been processed, for example, in the chemical liquid processing tank BT1 are alternately disposed.

The orientation changing unit 19 further includes a holding groove switching drive unit 71. The holding groove switching drive unit 71 includes at least one electric motor. The holding groove switching drive unit 71 rotates the first vertical holding unit 39 about the rotation axis AX5 and rotates the second vertical holding unit 40 about the rotation axis AX6. This can switch between a first state in which the plurality of pairs of reference pitch holding grooves 63A and 63B are usable, a second state in which the plurality of pairs of ⅔ pitch holding grooves 65A and 65B are usable, a third state in which the plurality of pairs of reference pitch holding grooves 67A and 67B are usable, and a fourth state in which the plurality of pairs of ⅔ pitch holding grooves 69A and 69B are usable. That is, the holding groove switching drive unit 71 can switch four states.

In the first state in which the plurality of pairs of reference pitch holding grooves 63A and 63B are usable, the plurality of pairs of reference pitch holding grooves 63A and 63B face each other (see FIG. 4). In the second state in which the plurality of pairs of ⅔ pitch holding grooves 65A and 65B are usable, the plurality of pairs of ⅔ pitch holding grooves 65A and 65B face each other (see FIG. 5). In the third state in which the plurality of pairs of reference pitch holding grooves 67A and 67B are usable, the plurality of pairs of reference pitch holding grooves 67A and 67B face each other. In the fourth state in which the plurality of pairs of ⅔ pitch holding grooves 69A and 69B are usable, the plurality of pairs of ⅔ pitch holding grooves 69A and 69B face each other.

In FIG. 6, the pair of vertical holding units 39 and 40 includes a plurality of pairs (for example, 18 pairs) of passage grooves 64A and 64B in addition to the plurality of pairs (for example, 17 pairs) of reference pitch holding grooves 63A and 63B. The plurality of pairs of reference pitch holding grooves 63A and 63B and the plurality of pairs of passage grooves 64A and 64B are alternately disposed. The plurality of pairs of passage grooves 64A and 64B are provided on the two outer peripheral 20 surfaces 55A and 55B. Similarly, the pair of vertical holding units 39 and includes a plurality of pairs (for example, 18 pairs) of passage grooves 68A and 68B in addition to the plurality of pairs (for example, 17 pairs) of reference pitch holding grooves 67A and 67B. The plurality of pairs of reference pitch holding grooves 67A and 67B and the plurality of pairs of passage grooves 68A and 68B are alternately disposed.

For example, in FIG. 6, for convenience of illustration, the pair of vertical holding units 39 and 40 includes three pairs of reference pitch holding grooves 63A and 63B and four pairs of passage grooves 64A and 64B. The three pairs of reference pitch holding grooves 63A and 63B and the four pairs of passage grooves 64A and 64B are alternately disposed. The width WD2 between the passage grooves 64A and 64B of each pair is set to be larger than the diameter of the substrate W. Thus, the passage grooves 64A and 64B of each pair can allow the two substrates W held by the pusher member 81 to pass therethrough. Similarly, when the passage grooves 68A and 68B of each pair face each other, the width of each pair of the passage grooves 68A and 68B is also set to be larger than the diameter of the substrate W.

In FIG. 7, the pair of vertical holding units 39 and 40 includes a plurality of pairs (for example, 26 pairs) of passage grooves 66A and 66B in addition to the plurality of pairs (for example, 25 pairs) of ⅔ pitch holding grooves 65A and 65B. The plurality of pairs of ⅔ pitch holding grooves 65A and 65B and the plurality of pairs of passage grooves 66A and 66B are alternately disposed. The plurality of pairs of passage grooves 66A and 66B are provided on the two outer peripheral surfaces 57A and 57B. Similarly, the pair of vertical holding units 39 and 40 includes a plurality of pairs (for example, 26 pairs) of passage grooves 70A and 70B in addition to the plurality of pairs (for example, 25 pairs) of ⅔ pitch holding grooves 69A and 69B. The plurality of pairs of ⅔ pitch holding grooves 69A and 69B and the plurality of pairs of passage grooves 70A and 70B are alternately disposed.

For example, in FIG. 7, for convenience of illustration, the pair of vertical holding units 39 and 40 includes four pairs of ⅔ pitch holding grooves 65A and 65B and five pairs of passage grooves 66A and 66B. The four pairs of ⅔ pitch holding grooves 65A and 65B and the five pairs of passage grooves 66A and 66B are alternately disposed. The width WD3 between the passage grooves 66A and 66B of each pair is also set to be larger than the diameter of the substrate W. Thus, the passage grooves 66A and 66B of each pair can allow one substrate W held by the pusher member 81 to pass therethrough. Similarly, when the passage grooves 70A and 70B of each pair face each other, the width of the passage grooves 70A and 70B of each pair is also set to be larger than the diameter of the substrate W.

When a plurality of substrates W aligned in a face-to-back manner are formed on the pusher member 81, the holding groove switching drive unit 71 switches to the first state in which the plurality of pairs of reference pitch holding grooves 63A and 63B are usable. When the plurality of substrates W held by the pusher member 81 are rearranged into a face to face manner, the holding groove switching drive unit 71 switches to the second state in which the plurality of pairs of ⅔ pitch holding grooves 65A and 65B are usable.

“Face-to-back” refers to an alignment state in which all front surfaces (front surface, main surface, or device surface) of a plurality of (for example, 50) substrates W face the same direction. “Face-to-face” refers to an alignment state in which the back surface or the front surface of two adjacent substrates W face each other. In other words, the face-to-face refers to an alignment state in which, when two or more first substrates W11 and two or more second substrates W12 are alternately disposed, the front surfaces of the two or more first substrates W11 face in a direction opposite to the front surfaces of the two or more second substrates W12. The device surface is a surface on which a device is to be formed or a surface on which a device is being formed.

When the plurality of substrates W held by the pusher member 81 are rearranged from the face-to-face manner to the face-to-back manner, the holding groove switching drive unit 71 switches to the fourth state in which the plurality of pairs of ⅔ pitch holding grooves 69A and 69B are usable. When the plurality of substrates W held by the pusher member 81 are divided into the three substrate groups, the holding groove switching drive unit 71 switches to the third state in which the plurality of pairs of reference pitch holding grooves 67A and 67B are usable.

As illustrated in FIG. 3, the orientation changing unit 19 further includes an accommodation moving unit 73. The accommodation moving unit 73 moves the pair of vertical holding units 39 and 40 close to or away from the pair of horizontal holding units 37 and 38. For example, when the pair of horizontal holding units 37 and 38 hold a plurality of substrates W in a horizontal orientation, the accommodation moving unit 73 can move the pair of vertical holding units 39 and 40 in the width directions Y. The accommodation moving unit 73 includes, for example, an electric actuator or an air cylinder. The electric actuator includes an electric motor.

See FIG. 4. When the accommodation moving unit 73 moves the vertical holding units 39 and 40 away from the horizontal holding units 37 and 38, the plurality of substrates W in a horizontal orientation are held only by the horizontal holding units 37 and 38 without using the vertical holding units 39 and 40. See FIG. 5. When the accommodation moving unit 73 moves the vertical holding units 39 and 40 close to the horizontal holding units 37 and 38, the peripheral edge portions of the plurality of substrates W can be accommodated by the plurality of pairs of ⅔ pitch holding grooves 65A and 65B at the position of the substrate W illustrated in FIG. 4, for example.

The rotation axis AX5 corresponds to a first rotation axis of the present invention. The rotation axis AX6 corresponds to a second rotation axis of the present invention. The outer peripheral surface 55A corresponds to a first outer peripheral surface of the present invention. The outer peripheral surface 57A corresponds to a second outer peripheral surface of the present invention. The outer peripheral surface 59A corresponds to a fifth outer peripheral surface of the present invention. The outer peripheral surface 61A corresponds to a sixth outer peripheral surface of the present invention. The outer peripheral surface 55B corresponds to a third outer peripheral surface of the present invention. The outer peripheral surface 57B corresponds to a fourth outer peripheral surface of the present invention. The outer peripheral surface 59B corresponds to a seventh outer peripheral surface of the present invention. The outer peripheral surface 61B corresponds to an eighth outer peripheral surface of the present invention.

The plurality of pairs of reference pitch holding grooves 67A and 67B correspond to a plurality of pairs of post-processing reference pitch holding grooves of the present invention. The plurality of pairs of ⅔ pitch holding grooves 69A and 69B correspond to a plurality of pairs of post-processing ⅔ pitch holding grooves of the present invention. The holding groove switching drive unit 71 corresponds to a switching drive unit of the present invention.

Next, details of the pusher mechanism 21 will be described. See FIGS. 8 and 9. The pusher mechanism 21 includes the pusher member 81 that holds a plurality of substrates W (for example, 50 substrates) aligned at a ⅓ pitch (for example, 3.333 mm pitch) that is ⅓ times a reference pitch (for example, 10 mm pitch) in a vertical orientation. The pusher mechanism 21 aligns the three substrate groups received from the orientation changing unit 19 in a row with the pusher member 81 while shifting the pusher member 81 by ⅓ pitch in the alignment direction (width direction Y) in which the plurality of substrates W is aligned. As a result, a plurality of (for example, 50) substrates W are formed on the pusher member 81. For the ⅓ pitch, the first interval TN1 (3.333 mm) is repeated.

The pusher mechanism 21 is disposed on the left side of the orientation changing unit 19 (see FIG. 1). As illustrated in FIG. 8, the pusher mechanism 21 includes the pusher member 81, a pusher rotating unit 85, a pusher horizontal moving unit 87, a lifting stage 89, and a pusher lifting unit 91. The pusher member 81 includes a plurality of (for example, 50 or 51) vertical holding grooves 93 disposed at a ⅓ pitch to hold a plurality of substrates W in a vertical orientation aligned at the ⅓ pitch.

The pusher rotating unit 85 rotates the pusher member 81 about a vertical axis AX7 passing through the center of the pusher member 81. This causes the plurality of substrates W supported in the vertical orientation by the pusher member 81 to rotate about the vertical axis AX7. The pusher rotating unit 85 includes, for example, an electric motor. The pusher rotating unit 85 is connected to the lower surface of the pusher member 81. The pusher rotating unit 85 is attached to the upper surface of the lifting stage 89 via the pusher horizontal moving unit 87.

The pusher horizontal moving unit 87 includes two guide rails 87A extending in the width directions Y, a slider 87B, and an electric motor (not illustrated). The two guide rails 87A are provided on the upper surface of the lifting stage 89. The slider 87B moves in the width directions Y along the two guide rails 87A. The slider 87B is driven by the electric motor. The pusher lifting unit 91 lifts and lowers the lifting stage 89 in the vertical directions Z. This causes the pusher member 81 to be lifted and lowered. The pusher lifting unit 91 includes, for example, an electric actuator.

See FIG. 1. The delivery mechanism 23 receives the plurality of substrates W aligned at a ⅓ pitch from the pusher member 81, and conveys the received plurality of substrates W to a delivery position P. At the delivery position P, the plurality of substrates W held by the delivery mechanism 23 are transferred to the main conveyance mechanism WTR. The delivery mechanism 23 includes a chuck 95, a width direction moving unit 97, and a guide rail 101. The width direction moving unit 97 can horizontally move the chuck 95 along the guide rail 101 extending in the width directions Y. The width direction moving unit 97 includes, for example, an electric actuator.

The chuck 95 holds a plurality of substrates W aligned at a ⅓ pitch in the width directions Y in a vertical orientation. The chuck 95 includes a pair of chuck members 95A and 95B extending in the width directions Y. The pair of chuck members 95A and 95B includes a plurality of pairs (for example, 50 pairs) of holding grooves disposed at a ⅓ pitch in the width directions Y.

When the plurality of vertical holding grooves 93 are disposed in the width directions Y, the pusher member 81 can pass between the pair of chuck members 95A and 95B in the vertical directions Z. The pair of chuck members 95A and 95B may be opened and closed in the front-back directions X.

### <1-4. Processing Block>

The processing block 7 includes a plurality of (for example, four) batch processing tanks BT1 to BT4 and a drying unit 103. The four batch processing tanks BT1 to BT4 and the drying unit 103 are disposed in the front-back directions X in which the substrate processing apparatus 1 extends. Each of the four batch processing tanks BT1 to BT4 collectively immerses and processes a plurality of (for example, 50) substrates W. Each of the four batch processing tanks BT1 to BT4 stores a processing liquid (for example, chemical liquid or pure water) for immersing the plurality of substrates W.

The four batch processing tanks BT1 to BT4 are formed of, for example, two chemical liquid processing tanks BT1 and BT3 and two cleaning processing tanks BT2 and BT4. The chemical liquid processing tank BT1 and the cleaning processing tank BT2 constitute one set, and the chemical liquid processing tank BT3 and the cleaning processing tank BT4 constitute the other set. The combination of the chemical liquid processing tank and the cleaning processing tank is not limited to this example. The number of batch processing tanks is not limited to four as long as it is one or more. At least one of the four batch processing tanks BT1 to BT4 corresponds to a substrate processing unit of the present invention.

Each of the two chemical liquid processing tanks BT1 and BT3 performs etching processing using a chemical liquid. For example, a phosphoric acid solution is used as the chemical liquid, but the chemical liquid is not limited to the phosphoric acid solution. The chemical liquid is heated to a preset temperature. A chemical liquid ejection pipe (not illustrated) is provided at the inner bottom of each of the chemical liquid processing tanks BT1 and BT3. Each of the chemical liquid processing tanks BT1 and BT3 stores the chemical liquid supplied from the chemical liquid ejection pipe.

Each of the two cleaning processing tanks BT2 and BT4 performs a cleaning processing of washing away the chemical liquid adhering to the plurality of substrates W with a cleaning liquid (rinse liquid). As the cleaning liquid, for example, pure water such as deionized water (DIW) is used. Each of the cleaning processing tanks BT2 and BT4 stores pure water supplied from a pure water ejection pipe (not illustrated).

The processing block 7 includes a lifter LF1 as a dedicated conveyance mechanism for transferring the substrate W subjected to the chemical liquid processing in the chemical liquid processing tank BT1 to the cleaning processing tank BT2, and a lifter LF2 for transferring the substrate W subjected to the chemical liquid processing in the chemical liquid processing tank BT3 to the cleaning processing tank BT4. Each of the two lifters LF1 and LF2 includes a substrate holding unit that holds a plurality of substrates W aligned at a ⅓ pitch in the width directions Y in a vertical orientation, a lift unit that lifts and lowers the substrate holding unit, and a horizontal moving unit that moves the substrate holding unit in the front-back directions X.

The drying unit 103 includes a substrate holding mechanism that holds a plurality of (for example, 50) substrates W aligned at a ⅓ pitch in the width directions Y in a vertical orientation, and a processing chamber that accommodates the plurality of substrates W held by the substrate holding mechanism. The drying unit 103 dries the substrates by supplying an organic solvent (for example, isopropyl alcohol) to the substrates W in a reduced-pressure atmosphere or removing liquid components on the surface of the substrates W using centrifugal force.

### <1-5. Batch Substrate Conveyance Region>

The batch substrate conveyance region 8 is disposed behind the stocker 2 and is adjacent to the transfer block 5 and the processing block 7 on the left side. The batch substrate conveyance region 8 extends in the front-back directions X. The batch substrate conveyance region 8 includes a main conveyance mechanism WTR (main conveyance robot). The main conveyance mechanism WTR conveys a plurality of (for example, 50) substrates W in a vertical orientation aligned at a ⅓ pitch in the width directions Y in the front-back directions X. The main conveyance mechanism WTR conveys the plurality of substrates W between the delivery position P, the plurality of (for example, four) batch processing tanks BT1 to BT4, and the drying unit 103.

The main conveyance mechanism WTR includes a chuck 105, a chuck lifting unit (not illustrated), a chuck horizontal moving unit (not illustrated), and a guide rail 107. The chuck 105 holds a plurality of substrates W aligned at a ⅓ pitch in the width directions Y in a vertical orientation. The chuck 105 includes a pair of chuck members 105A and 105B extending in the width directions Y. The pair of chuck members 105A and 105B includes a plurality of pairs (for example, 50 or 51 pairs) of holding grooves disposed at a ⅓ pitch in the width directions Y. The pair of chuck members 105A and 105B is opened and closed by a chuck opening and closing unit (not illustrated).

The chuck 105 is movable in the front-back directions X along the guide rail 107. The chuck 105 is moved in the front-back directions X by the chuck horizontal moving unit. The chuck 105 is lifted and lowered in the vertical directions Z by the chuck lifting unit. The chuck horizontal moving unit and the chuck lifting unit include, for example, an electric actuator. The chuck opening and closing unit includes, for example, an electric actuator or an air cylinder.

### <1-6. Controller>

The substrate processing apparatus 1 includes a controller 111 and a storage unit (not illustrated). The controller 111 controls each configuration of the substrate processing apparatus 1. The controller 111 includes one or more processors such as a central processing unit (CPU). The storage unit includes, for example, at least one of a read-only memory (ROM), a random-access memory (RAM), and a hard disk. The storage unit stores a computer program necessary for controlling each configuration of the substrate processing apparatus 1.

### <2. Operation of Substrate Processing Apparatus>

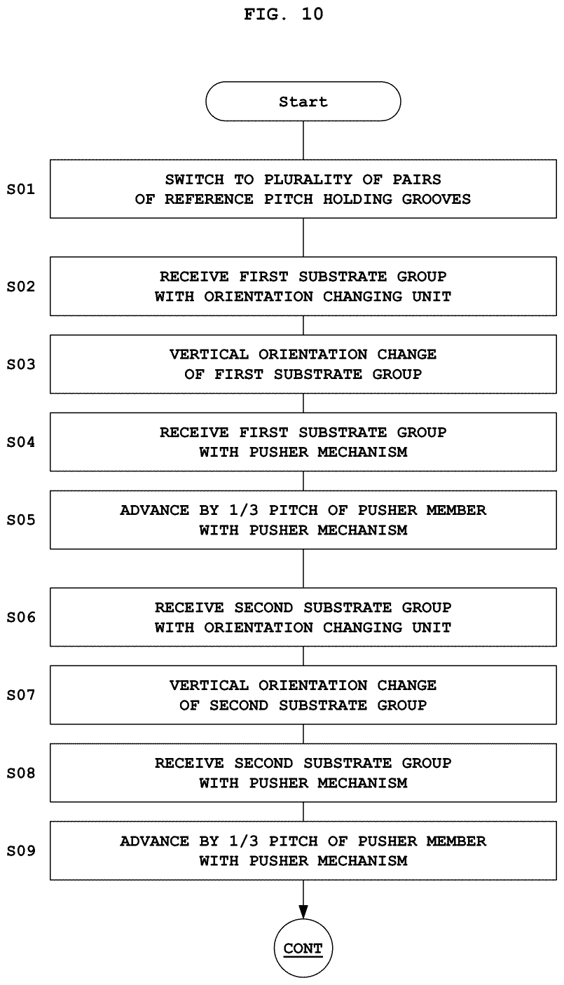

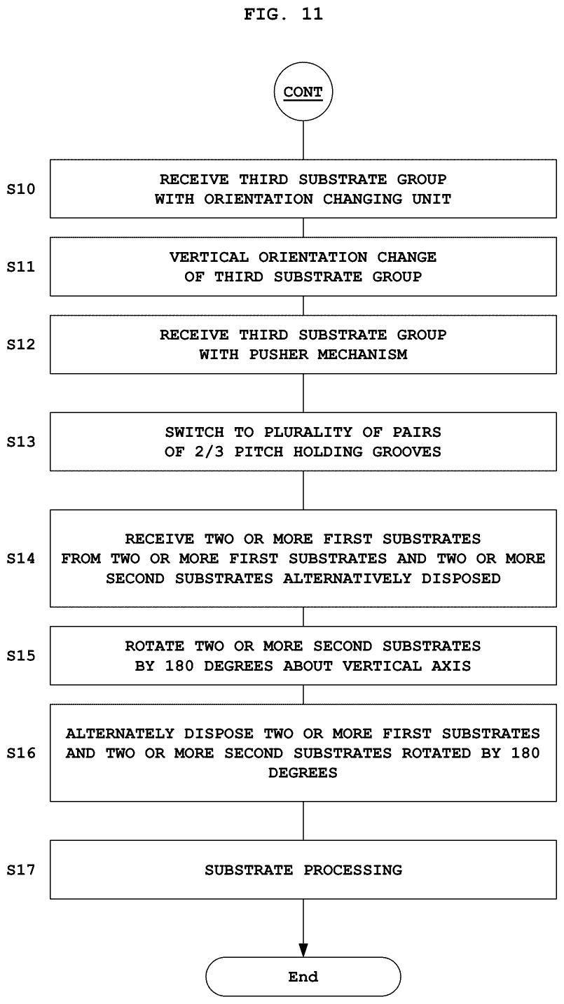

Next, the operation of the substrate processing apparatus 1 will be described with reference to the flowcharts of FIGS. 10 and 11.

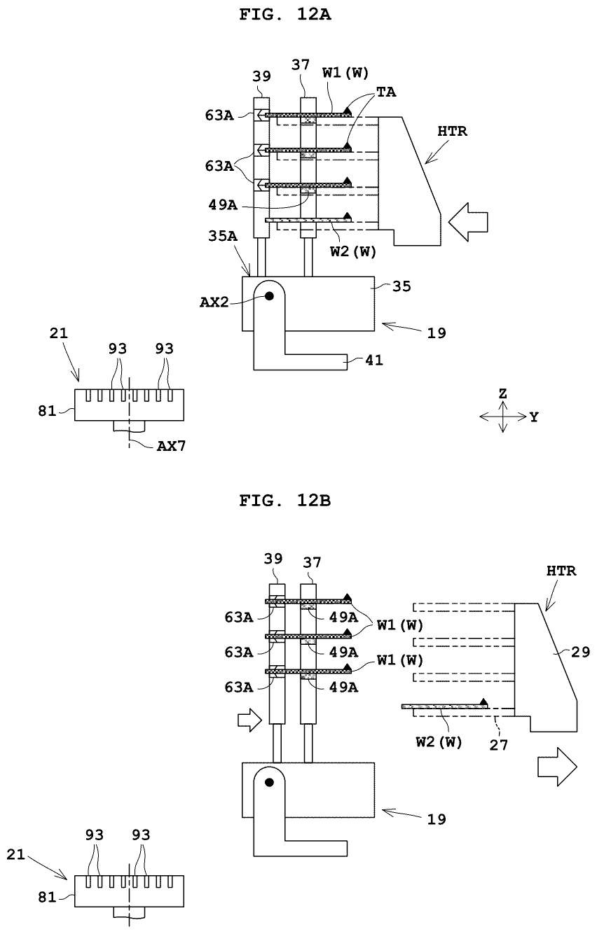

In FIG. 12A and the like, a reference sign TA indicates a front surface (front surface, device surface, or main surface) of the substrate W (W1, W2, W3). In FIG. 12A and the like, for convenience of illustration, 17 substrates W1 are illustrated by three substrates W1, and 17 substrates W2 are illustrated by three substrates W2. In addition, 16 substrates W3 are illustrated by two substrates W3.

The substrate handling mechanism HTR includes 25 hands 27. The pair of horizontal holding units 37 and 38 includes 17 pairs of pre-processing shelves 49A and 49B and 17 pairs of post-processing shelves 51A and 51B. The pusher member 81 includes 51 vertical holding grooves 93.

The pair of vertical holding units 39 and 40 includes 17 pairs of reference pitch holding grooves 63A and 63B and 25 pairs of ⅔ pitch holding grooves 65A and 65B to handle the substrates W before processing. The pair of vertical holding units 39 and 40 includes 17 pairs of reference pitch holding grooves 67A and 67B and 25 pairs of ⅔ pitch holding grooves 69A and 69B to handle the substrates W after processing.

See FIG. 1. An external conveyance robot (not illustrated) sequentially conveys two carriers C to the load port 9. The carrier conveyance robot 13 conveys the first carrier C from the load port 9 to the placement shelf 3. It is assumed that 25 substrates W1 and W2 (17 substrates W1 and 8 substrates W2) aligned at a reference pitch (for example, 10 mm) are stored in a first carrier C.

### [Step S01] Switching to Plurality of Pairs of Reference Pitch Holding Grooves

First, the holding groove switching drive unit 71 of the orientation changing unit 19 rotates the first vertical holding unit 39 about the rotation axis AX5 and rotates the second vertical holding unit 40 about the rotation axis AX6. With this operation, the holding groove switching drive unit 71 switches to the first state in which the 17 pairs of reference pitch holding grooves 63A and 63B are usable. The shelf switching drive unit 53 of the orientation changing unit 19 switches to the state in which the 17 pairs of pre-processing shelves 49A and 49B are usable.

Here, an outline of operations in steps S02 to S12 will be described. The orientation changing unit 19 sequentially receives three substrate groups (first substrate group, second substrate group, and third substrate group) from the substrate handling mechanism HTR. The orientation changing unit 19 individually changes the orientation of the three substrate groups from a horizontal orientation to a vertical orientation. The pusher mechanism 21 causes the pusher member 81 to sequentially receive the three substrate groups while shifting the pusher member 81 by ⅓ pitch in the alignment direction (width direction Y) of the 50 substrates W (W1, W2, W3). As a result, the pusher member 81 holds 50 substrates W formed from the three substrate groups and aligned in a face-to-back manner at a ⅓ pitch. These operations will be described in order.

[Step S02] Reception of First Substrate Group with Orientation Changing Unit

See FIGS. 1 and 12A. The substrate handling mechanism HTR takes out 25 substrates W1 and W2 from the first carrier C placed on the placement shelf 3. Thereafter, the substrate handling mechanism HTR conveys 17 substrates W1 out of the taken out 25 substrates W1 and W2 to the orientation changing unit 19. The orientation changing unit 19 receives 17 substrates W1 (first substrate group) from the substrate handling mechanism HTR using 17 pairs of pre-processing shelves 49A and 49B of the horizontal holding units 37 and 38.

The carrier conveyance robot 13 moves the empty first carrier C from which the 25 substrates W1 and W2 have been taken out from the placement shelf 3 to the storage shelf 11. The carrier conveyance robot 13 also conveys a second carrier C from the load port 9 to the placement shelf 3. It is assumed that 25 substrates W2 and W3 (9 substrates W2 and 16 substrates W3) are stored in the second carrier C.

See FIG. 12B. The pair of horizontal holding units 37 and 38 holds 17 substrates W1 in a horizontal orientation. At this time, the front surfaces of the 17 substrates W1 are upward as indicated by the reference sign TA. The substrate handling mechanism HTR holds the remaining eight substrates W2 with eight hands 27 among the 25 hands 27.

Thereafter, the accommodation moving unit 73 (see FIG. 3) of the orientation changing unit 19 moves the vertical holding units 39 and 40 close to the horizontal holding units 37 and 38. As a result, the 17 pairs of reference pitch holding grooves 63A and 63B of the vertical holding units 39 and 40 accommodate the peripheral edge portions of the 17 substrates W1 in a horizontal orientation held (placed) by the horizontal holding units 37 and 38.

### [Step S03] Vertical Orientation Change of First Substrate Group

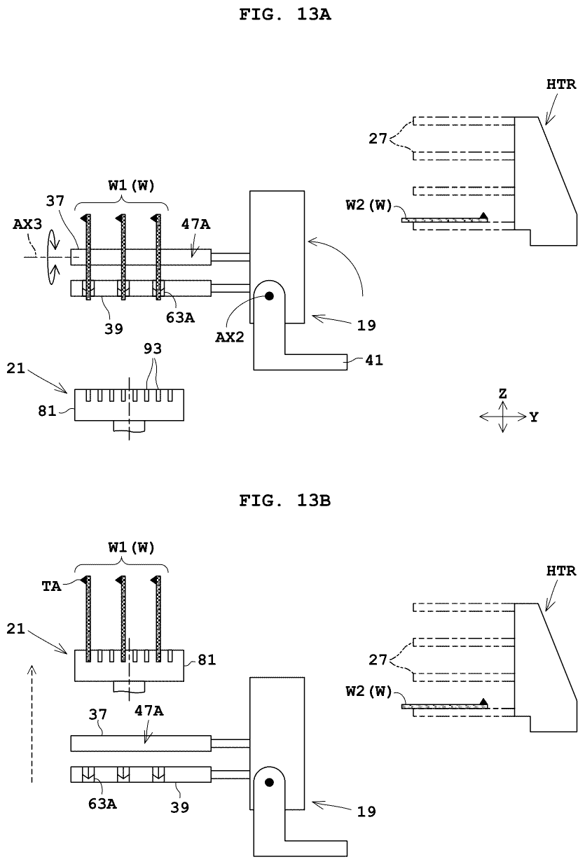

See FIG. 13A. The rotation drive unit 41 of the orientation changing unit 19 rotates the horizontal holding units 37 and 38 and the vertical holding units 39 and 40 by 90 degrees about the horizontal axis AX2. As a result, the orientation of the 17 substrates W1 (first substrate group) held by the horizontal holding units 37 and 38 and the vertical holding units 39 and 40 are changed from a horizontal orientation to a vertical orientation.

Thereafter, the shelf switching drive unit 53 rotates the first horizontal holding unit 37 about the rotation axis AX3 and rotates the second horizontal holding unit 38 about the rotation axis AX4. With this operation, the shelf switching drive unit 53 switches from the state in which the 17 pairs of pre-processing shelves 49A and 49B are usable to the state in which the first retraction surface 47A and the second retraction surface 47B are usable. That is, the shelf switching drive unit 53 retracts each of the 17 pairs of pre-processing shelves 49A and 49B from the position on the back surface side of the 17 substrates W1.

[Step S04] Reception of First Substrate Group with Pusher Mechanism

See FIG. 13B. Thereafter, the pusher mechanism 21 lifts the pusher member 81 that does not hold a substrate to a position higher than the horizontal holding units 37 and 38. With this operation, the pusher member 81 receives the 17 substrates W1 (first substrate group) from the 17 pairs of reference pitch holding grooves 63A and 63B of the vertical holding units 39 and 40. The pusher member 81 holds 17 substrates W1 aligned at a reference pitch (10 mm pitch) in a vertical orientation. At this time, the front surfaces of the 17 substrates W1 face leftward.

[Step S05] ⅓ Pitch Advance of Pusher Member with Pusher Mechanism

See FIG. 14A. The pusher horizontal moving unit 87 (see FIG. 8) of the pusher mechanism 21 moves the pusher member 81 leftward by the first interval TN1 (for example, 3.333 mm). The first interval TN1 is an interval of ⅓ times the reference interval TN9 constituting the reference pitch. With such movement, the pusher member 81 can receive the next 17 substrates W2 (second substrate group) at a position separated from the 17 substrates W1 by the first interval TN1. In addition, 17 substrates W1 (first substrate group) and 17 substrates W2 (second substrate group) can be alternately disposed.

The rotation drive unit 41 of the orientation changing unit 19 rotates the horizontal holding units 37 and 38 and the vertical holding units 39 and by 90 degrees about the horizontal axis AX2. The horizontal holding units 37 and 38 and the like thus rise. The accommodation moving unit 73 (see FIG. 3) of the orientation changing unit 19 moves the vertical holding units 39 and 40 away from the horizontal holding units 37 and 38. The shelf switching drive unit 53 rotates the first horizontal holding unit 37 about the rotation axis AX3 and rotates the second horizontal holding unit 38 about the rotation axis AX4. With this operation, the shelf switching drive unit 53 switches from the state in which the first retraction surface 47A and the second retraction surface 47B are usable to the state in which the 17 pairs of pre-processing shelves 49A and 49B are usable. This allows the 17 pairs of pre-processing shelves 49A and 49B to receive the next 17 substrates W2.

[Step S06] Reception of Second Substrate Group with Orientation Changing Unit

See FIG. 14B. The substrate handling mechanism HTR conveys the remaining eight substrates W2 held by eight hands 27 among the 25 hands 27 in the first carrier C to the orientation changing unit 19. The orientation changing unit 19 receives eight substrates W2 from the substrate handling mechanism HTR using eight pairs of pre-processing shelves 49A and 49B out of the 17 pairs of pre-processing shelves 49A and 49B.

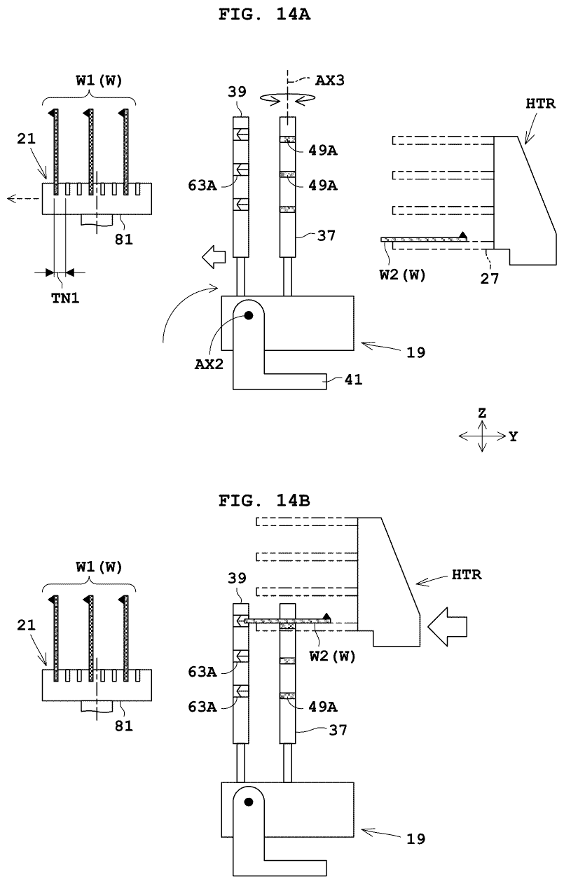

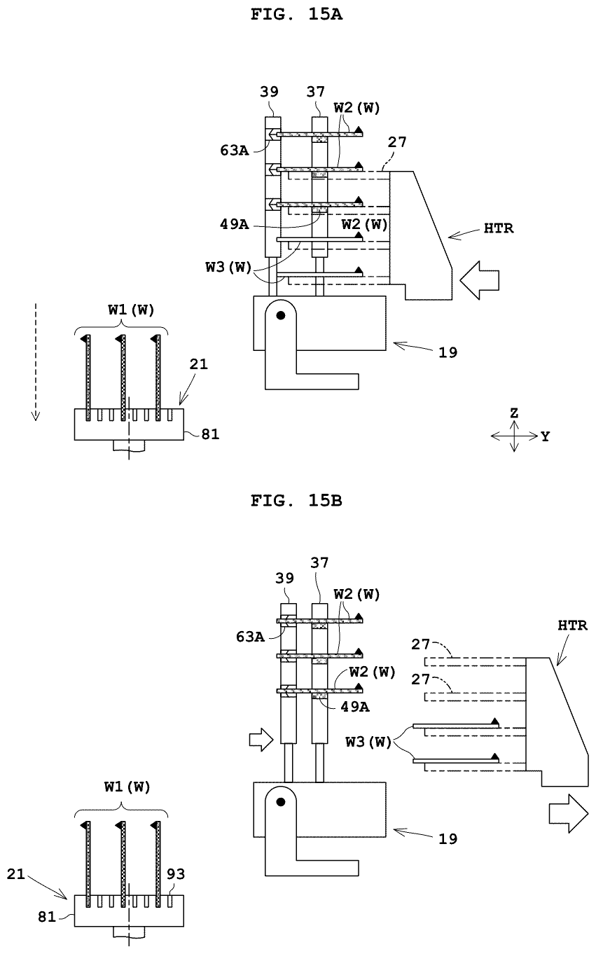

See FIG. 15A. Thereafter, the substrate handling mechanism HTR takes out 25 substrates W2 and W3 from the second carrier C placed on the placement shelf 3. Thereafter, the substrate handling mechanism HTR conveys nine substrates W2 out of the taken out 25 substrates W2 and W3 to the orientation changing unit 19. The orientation changing unit 19 receives nine substrates W2 from the substrate handling mechanism HTR using nine pairs of pre-processing shelves 49A and 49B out of the 17 pairs of pre-processing shelves 49A and 49B. The horizontal holding units 37 and 38 of the orientation changing unit 19 hold 17 substrates W2 (second substrate group) including eight substrates W2 of the first carrier C and nine substrates W2 of the second carrier C in a horizontal orientation.

The pusher mechanism 21 lowers the pusher member 81 holding the 17 substrates W1 in a vertical orientation to a height position at which the next 17 substrates W2 can be received.

See FIG. 15B. Thereafter, the accommodation moving unit 73 (see FIG. 3) of the orientation changing unit 19 moves the vertical holding units 39 and 40 close to the horizontal holding units 37 and 38. As a result, the 17 pairs of reference pitch holding grooves 63A and 63B accommodate the peripheral edge portions of the 17 substrates W2 in the horizontal orientation held (placed) by the horizontal holding units 37 and 38.

### [Step S07] Vertical Orientation Change of Second Substrate Group

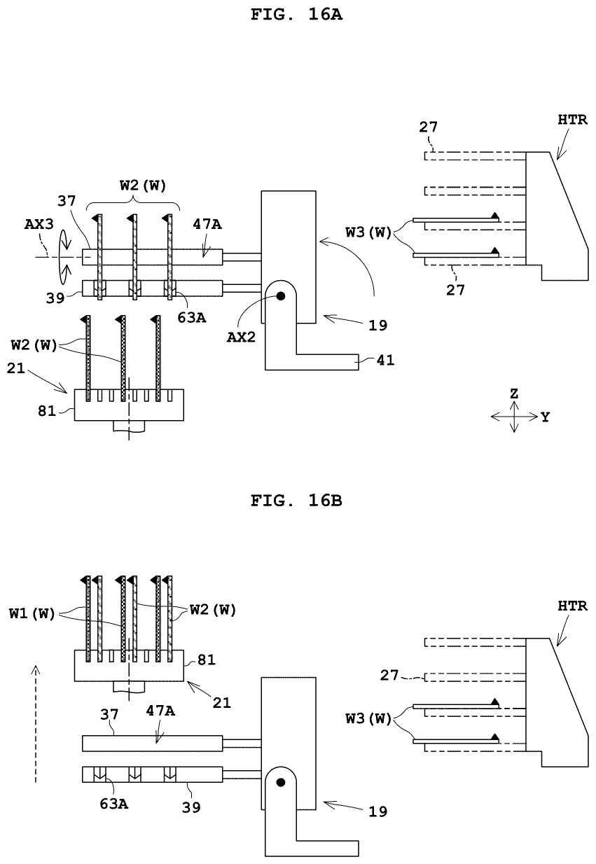

See FIG. 16A. After moving the vertical holding units 39 and 40 close to the horizontal holding unit 37 and 38, the orientation changing unit 19 rotates the horizontal holding units 37 and 38 and the vertical holding units 39 and 40 by 90 degrees about the horizontal axis AX2. This causes the orientation changing unit 19 to change the orientation of the 17 substrates W2 (second substrate group) from a horizontal orientation to a vertical orientation. Thereafter, the shelf switching drive unit 53 switches from the state in which the 17 pairs of pre-processing shelves 49A and 49B are usable to the state in which the first retraction surface 47A and the second retraction surface 47B are usable.

[Step S08] Reception of Second Substrate Group with Pusher Mechanism

See FIG. 16B. Thereafter, the pusher mechanism 21 lifts the pusher member 81. With this operation, the pusher member 81 receives the 17 substrates W2 (second substrate group) from the vertical holding units 39 and 40. Further, the pusher member 81 holds the 17 substrates W2 aligned at a reference pitch (10 mm pitch) in a vertical orientation. In other words, the pusher member 81 holds the 17 substrates W1 and the 17 substrates W2 alternately disposed. At this time, the front surfaces of the 17 substrates W2 face leftward.

[Step S09] ⅓ Pitch Advance of Pusher Member with Pusher Mechanism

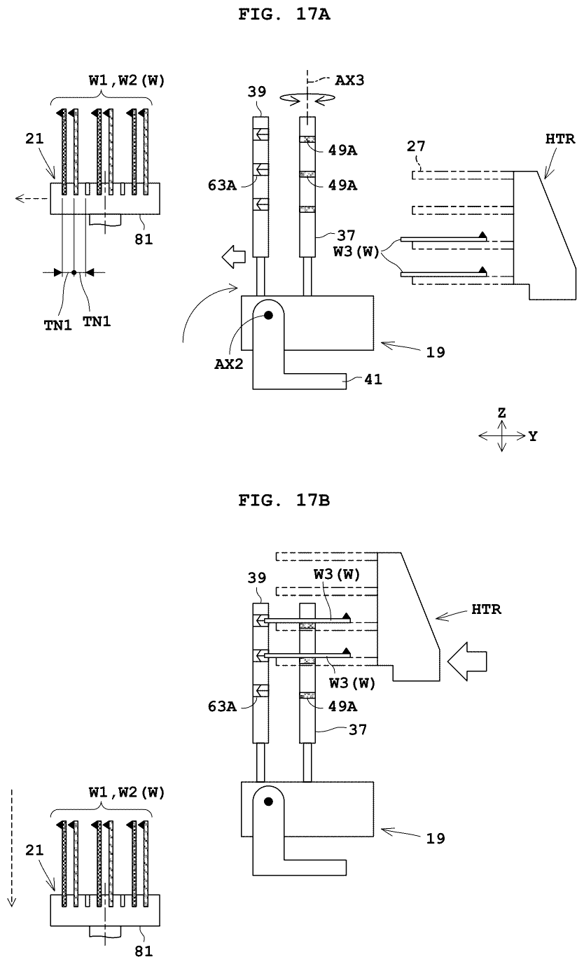

See FIG. 17A. The pusher mechanism 21 further moves the pusher member 81 leftward by the first interval TN1 (3.333 mm). With such movement, the pusher member 81 can receive the next 16 substrates W3 (third substrate group) at a position separated from the 17 substrates W2 by the first interval TN1. In addition, the pusher member 81 can sequentially and repeatedly dispose 17 substrates W1, 17 substrates W2, and 16 substrates W3 one by one.

The orientation changing unit 19 rotates the horizontal holding units 37 and 38 and the vertical holding units 39 and 40 by 90 degrees about the horizontal axis AX2. The horizontal holding units 37 and 38 and the like thus rise. The accommodation moving unit 73 (see FIG. 3) moves the vertical holding units 39 and 40 away from the horizontal holding units 37 and 38. The shelf switching drive unit 53 switches from the state in which the first retraction surface 47A and the second retraction surface 47B are usable to the state in which the 17 pairs of pre-processing shelves 49A and 49B are usable. This allows the 17 pairs of pre-processing shelves 49A and 49B to receive the next 16 substrates W3.

[Step S10] Reception of Third Substrate Group with Orientation Changing Unit

See FIG. 17B. The substrate handling mechanism HTR conveys the remaining 16 substrates W3 in the second carrier C held by 16 hands 27 among the 25 hands 27 to the orientation changing unit 19. The orientation changing unit 19 receives the 16 substrates W3 (third substrate group) from the substrate handling mechanism HTR using 16 pairs of pre-processing shelves 49A and 49B out of the 17 pairs of pre-processing shelves 49A and 49B. The horizontal holding units 37 and 38 hold the 16 substrates W3 (third substrate group) of the second carrier C in a horizontal orientation.

The pusher mechanism 21 lowers the pusher member 81 holding the 34 substrates W1 and W2 in a vertical orientation to a height position at which the next 16 substrates W3 can be received.

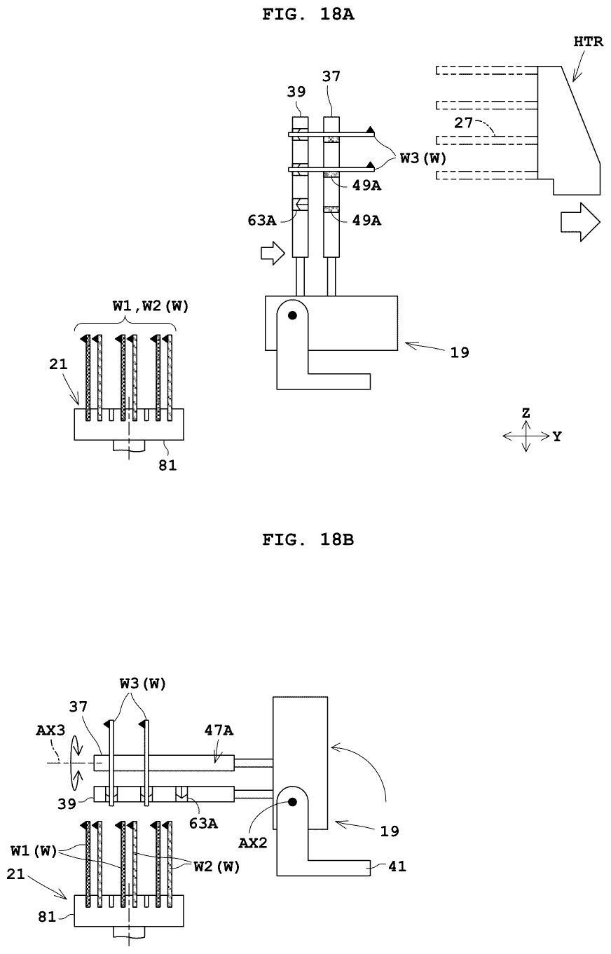

See FIG. 18A. Thereafter, the accommodation moving unit 73 (see FIG. 3) moves the vertical holding units 39 and 40 close to the horizontal holding units 37 and 38.

### [Step S11] Vertical Orientation Change of Third Substrate Group

See FIG. 18B. Thereafter, the orientation changing unit 19 rotates the horizontal holding units 37 and 38 and the vertical holding units 39 and by 90 degrees about the horizontal axis AX2. This causes the orientation changing unit 19 to change the orientation of the 16 substrates W3 (third substrate group) from a horizontal orientation to a vertical orientation. Thereafter, the shelf switching drive unit 53 switches from the state in which the 17 pairs of pre-processing shelves 49A and 49B are usable to the state in which the first retraction surface 47A and the second retraction surface 47B are usable.

[Step S12] Reception of Third Substrate Group with Pusher Mechanism

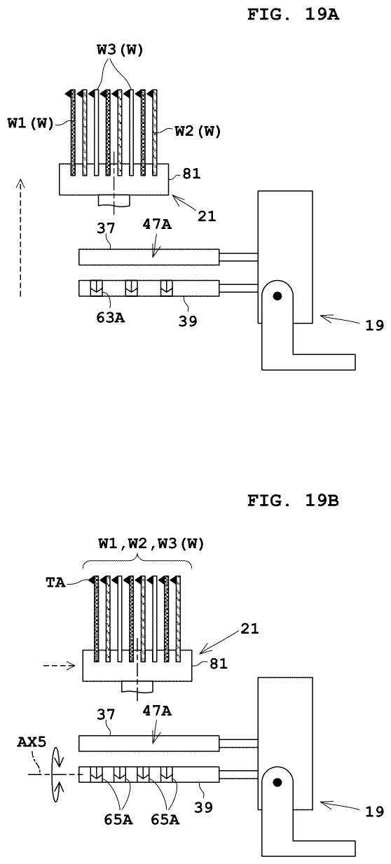

See FIG. 19A. Thereafter, the pusher mechanism 21 lifts the pusher member 81. With this operation, the pusher member 81 receives the 16 substrates W3 (third substrate group) from the vertical holding units 39 and 40. Further, the pusher member 81 holds 16 substrates W3 aligned at a reference pitch (10 mm pitch) in a vertical orientation. The pusher member 81 holds 50 substrates W (processing substrate group) in which 17 substrates W1, 17 substrates W2, and 16 substrates W3 are sequentially disposed one by one. At this time, the front surfaces of the 16 substrates W3 face leftward. That is, all the front surfaces of the 50 substrates W face leftward. Thus, the pusher member 81 holds 50 substrates W aligned in a face-to-back manner. The pusher member 81 holds the 50 substrates W aligned at a ⅓ pitch.

### [Step S13] Switching to Plurality of Pairs of ⅔ Pitch Holding Grooves

See FIG. 19B. The holding groove switching drive unit 71 rotates the first vertical holding unit 39 about the rotation axis AX5 and rotates the second vertical holding unit 40 about the rotation axis AX6. With this operation, the holding groove switching drive unit 71 switches from the first state in which the 17 pairs of reference pitch holding grooves 63A and 63B are usable to the second state in which the 25 pairs of ⅔ pitch holding grooves 65A and 65B are usable.

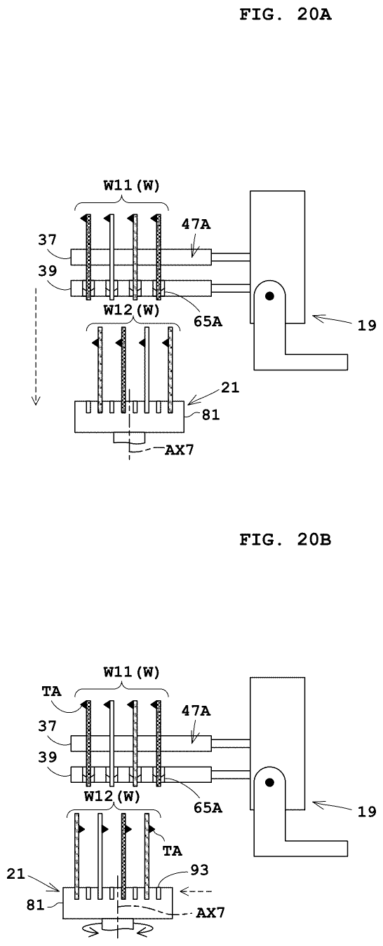

The pusher mechanism 21 horizontally moves the pusher member 81 holding the 50 substrates W in a vertical orientation in the alignment direction (width direction Y) of the 50 substrates W. At this time, the pusher member 81 is moved rightward, for example. As a result, as illustrated in FIG. 20A, 25 pairs of ⅔ pitch holding grooves 65A and 65B of the vertical holding unit 39 and 40 can extract, for example, 25 first substrates W11 from 50 substrates W (W1, W2, W3). It is assumed that the 50 substrates W (W1, W2, W3) include 25 first substrates W11 and 25 second substrates W12 alternately disposed. In other words, the 50 substrates W including the substrates W1, W2, and W3 are grouped into 25 first substrates W11 and 25 second substrates W12.

[Step S14] Reception of Two or More First Substrates from Two or More First Substrates and Two or More Second Substrates Alternatively Disposed

See FIG. 20A. The pusher mechanism 21 lowers the pusher member 81 holding the 50 substrates W in a vertical orientation to a height position lower than the vertical holding units 39 and 40. The vertical holding units 39 and 40 are in the second state in which the 25 pairs of ⅔ pitch holding grooves 65A and 65B face each other, and the 25 pairs of ⅔ pitch holding grooves 65A and 65B are usable.

Thus, the vertical holding units 39 and 40 receive, from the pusher member 81, 25 first substrates W11 aligned at a ⅔ pitch (for example, 6.666 mm pitch) among the 50 substrates W in which 25 first substrates W11 and 25 second substrates W12 are alternately disposed. At this time, the 25 first substrates W11 are held by 25 pairs of ⅔ pitch holding grooves 65A and 65B. The 25 second substrates W12 are passed through, for example, 26 pairs of passage grooves 66A and 66B illustrated in FIG. 7. The 25 first substrates W11 are aligned at ⅔ pitch, and the 25 second substrates W12 are also aligned at ⅔ pitch. For the ⅔ pitch, the second interval TN2 (6.666 mm) is repeated.

In this description, the vertical holding units 39 and 40 receive 25 first substrates W11 out of 50 substrates W from the pusher member 81. In this regard, the vertical holding units 39 and 40 may receive 25 second substrates W12 out of 50 substrates W from the pusher member 81.

### [Step S15] Rotation of Two or More Second Substrates by 180 Degrees About Vertical Axis

See FIG. 20B. The pusher rotating unit 85 (see FIG. 8) of the pusher mechanism 21 rotates the pusher member 81 holding 25 second substrates W12 in a vertical orientation by 180 degrees about the vertical axis AX7. As a result, the front surfaces of the 25 second substrates W12 face from the left to the right. The pusher horizontal moving unit 87 of the pusher mechanism 21 may horizontally move the pusher member 81 holding the 25 second substrates W12 leftward. This allows 25 vertical holding grooves 93 that do not hold the substrates W to receive the 25 first substrates W11 held by the vertical holding units 39 and 40.

### [Step S16] Alternate Disposition of Two or More First Substrates and Two or More Second Substrates Rotated by 180 Degrees

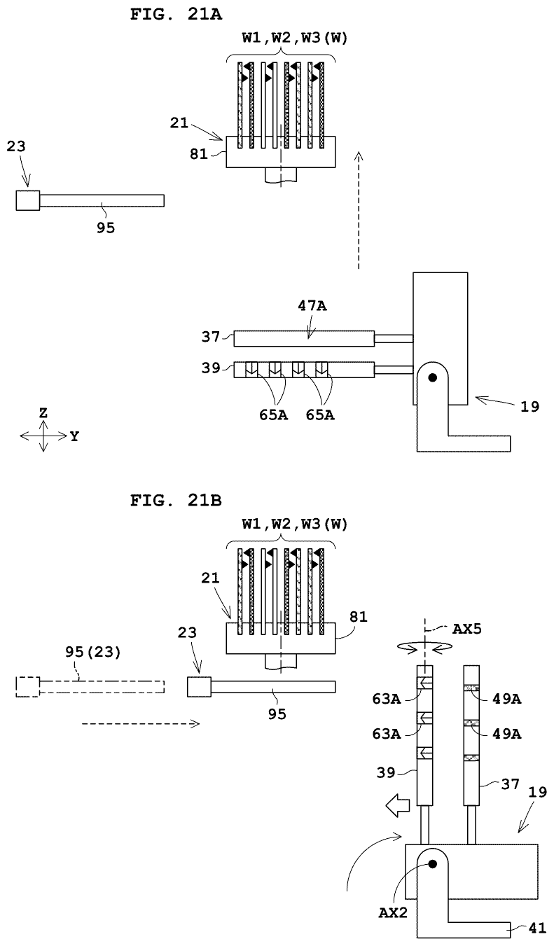

See FIG. 21A. The pusher mechanism 21 lifts the pusher member 81 holding the 25 second substrates W12 that have been rotated by 180 degrees. With this operation, the pusher member 81 receives the 25 first substrates W11 from the vertical holding units 39 and 40. The reception of the 25 first substrates W11 is performed while the 25 first substrates W11 and the 25 second substrates W12 rotated by 180 degrees are alternately disposed.

As illustrated in FIG. 20B, the front surfaces of the 25 first substrates W11 that are not rotated by 180 degrees face leftward. On the other hand, the 25 second substrates W12 rotated by 180 degrees face rightward. Thus, the pusher member 81 illustrated in FIG. 21A holds 50 substrates W aligned in a face-to-face manner. The pusher member 81 holds the 50 substrates W aligned at a ⅓ pitch.

### [Step S17] Substrate Processing

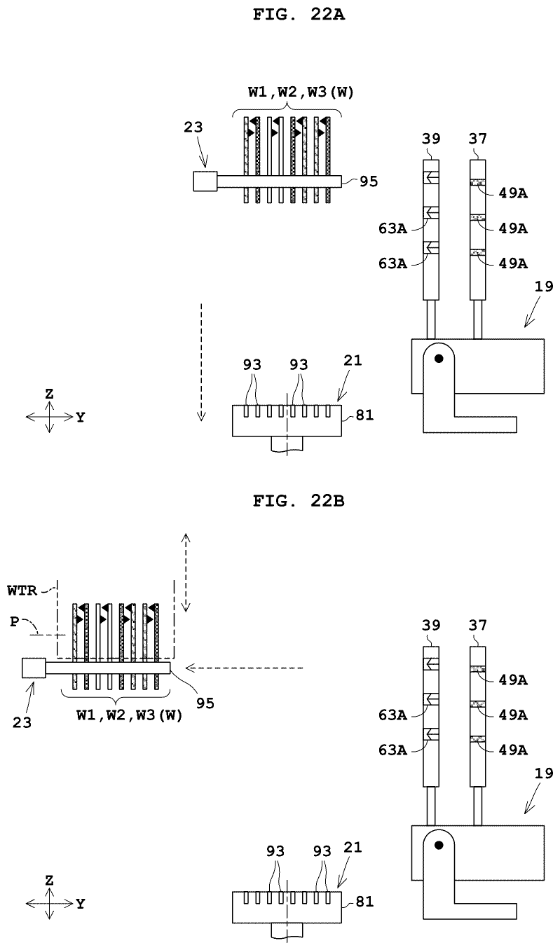

See FIG. 21B. The delivery mechanism 23 horizontally moves the chuck 95 below the pusher member 81 that holds the 50 substrates W in a vertical orientation. See FIG. 22A. Thereafter, the pusher mechanism 21 lowers the pusher member 81. With this operation, the chuck 95 receives 50 substrates W in a vertical orientation, which are aligned in a face-to-face manner at a ⅓ pitch, from the pusher member 81. See FIG. 22B. Thereafter, the delivery mechanism 23 moves the chuck 95 holding the 50 substrates W to the delivery position P.

See FIG. 1. Thereafter, the main conveyance mechanism WTR receives the 50 substrates W in a vertical orientation from the chuck 95 using the chuck 105 at the delivery position P. Thereafter, the main conveyance mechanism WTR conveys the 50 substrates W aligned at a ⅓ pitch in a face-to-face manner to one of the two chemical liquid processing tanks BT1 and BT3. For example, when the main conveyance mechanism WTR conveys the 50 substrates W to the chemical liquid processing tank BT1, the lifter LF1 receives the 50 substrates W aligned at a ⅓ pitch from the main conveyance mechanism WTR at a position above the chemical liquid processing tank BT1. The 50 substrates W are aligned in a face-to-face manner. Thereafter, the lifter LF1 immerses the 50 substrates W in the chemical liquid stored in the chemical liquid processing tank BT1 by lowering the 50 substrates W. As a result, the 50 substrates W are collectively subjected to chemical liquid processing.

After a preset chemical liquid processing time has elapsed, the lifter LF1 pulls up the 50 substrates W from the chemical liquid in the chemical liquid processing tank BT1 by lifting the 50 substrates W. Thereafter, the lifter LF1 horizontally moves the 50 substrates W from the upper position of the chemical liquid processing tank BT1 to the upper position of the cleaning processing tank BT2. Thereafter, the lifter LF1 immerses the 50 substrates W in the pure water stored in the cleaning processing tank BT2 by lowering the 50 substrates W. As a result, the 50 substrates W are collectively subjected to cleaning processing. After a preset cleaning processing time has elapsed, the lifter LF1 pulls up the 50 substrates W from the pure water in the cleaning processing tank BT2.

When the main conveyance mechanism WTR conveys the 50 substrates W to the chemical liquid processing tank BT3, the lifter LF2 receives the 50 substrates W from the main conveyance mechanism WTR. Then, the lifter LF2 conveys the 50 substrates W in order of the chemical liquid processing tank BT3 and the cleaning processing tank BT4.

The main conveyance mechanism WTR uses the chuck 105 to receive the 50 substrates W from one of the two lifters LF1 and LF2 and conveys the 50 substrates W to the drying unit 103. The drying unit 103 dries the 50 substrates W. Thereafter, the main conveyance mechanism WTR receives the dried 50 substrates W from the drying unit 103. The main conveyance mechanism WTR conveys the 50 substrates W subjected to the drying processing to the delivery position P.

Next, a conveyance operation for the 50 substrates W after processing will be described. This conveyance operation is performed in the reverse order of FIGS. 12A to 22B.

First, the delivery mechanism 23 uses the chuck 95 to receive the 50 substrates W after processing from the main conveyance mechanism WTR at the delivery position P. The 50 substrates W in a vertical orientation are aligned in a face-to-face manner at a ⅓ pitch. Thereafter, the delivery mechanism 23 moves the chuck 95 holding the 50 substrates W above the pusher member 81. Thereafter, the pusher mechanism 21 lifts the pusher 30 member 81. With this operation, the pusher member 81 receives the 50 substrates W from the chuck 95.

Thereafter, the 50 substrates W aligned in a face-to-face manner are rearranged to be aligned in a face-to-back manner as illustrated in the order of FIGS. 21A, 20B, and 20A. At this time, the horizontal holding units 37 and 38 and the like lie down (see FIG. 21A). The vertical holding units 39 and 40 are brought close to the horizontal holding units 37 and 38. The holding groove switching drive unit 71 switches to the fourth state in which the 25 pairs of ⅔ pitch holding grooves 69A and 69B for post processing are usable.

Thereafter, as illustrated in the order of FIG. 19B, FIG. 19A, FIG. 18B, FIG. 18A, FIG. 17B, FIG. 17A, FIG. 16B, FIG. 16A, FIG. 15B, FIG. 15A, FIG. 14B, FIG. 14A, FIG. 13B, FIG. 13A, FIG. 12B, and FIG. 12A, the 50 substrates W are divided into three substrate groups. The three substrate groups are the first substrate group (17 substrates W1), the second substrate group (17 substrates W2), and the third substrate group (16 substrates W3).

When the substrates W are divided into the three substrate groups held by the pusher member 81, the holding groove switching drive unit 71 switches to the third state in which 17 pairs of reference pitch holding grooves 67A and 67B for post processing are usable. When individually holding three substrate groups of the 50 substrates W after processing in a horizontal orientation, the shelf switching drive unit 53 switches to the state 20) in which the plurality of pairs of post-processing shelves 51A and 51B are usable. When delivering a plurality of substrates W between the pair of vertical holding units 39 and 40 (orientation changing unit 19) and the pusher member 81 (pusher mechanism 21), the shelf switching drive unit 53 switches to the state in which the first retraction surface 47A and the second retraction surface 47B are usable.

Thereafter, the substrate handling mechanism HTR stores the 25 substrates W2 and W3 (9 substrates W2 and 16 substrates W3) after processing in the second carrier C placed on the placement shelf 3. The substrate handling mechanism HTR stores the 25 substrates W1 and W2 (17 substrates W1 and 8 substrates W2) after processing in the first carrier C placed on the placement shelf 3.

The carrier conveyance robot 13 conveys the first carrier C in which the 25 substrates W1 and W2 after processing from the placement shelf 3 to the load port 9. The carrier conveyance robot 13 conveys the second carrier C in which the 25 substrates W2 and W3 after processing from the placement shelf 3 to the load port 9. An external conveyance robot (not illustrated) sequentially conveys two carriers C from the load port 9 to the next destination.

According to the present embodiment, the pair of vertical holding units 39 and 40 of the orientation changing unit 19 includes the plurality of pairs of reference pitch holding grooves 63A and 63B and the plurality of pairs of ⅔ pitch holding grooves 65A and 65B. The plurality of pairs of reference pitch holding grooves 63A and 63B are disposed at a reference pitch. The plurality of pairs of ⅔ pitch holding grooves 65A and 65B are disposed at a ⅔ pitch that is ⅔ times the reference pitch. The holding groove switching drive unit 71 switches to the state in which the plurality of pairs of reference pitch holding grooves 63A and 63B are usable. With this operation, the pusher mechanism 21 can cause the pusher member 81 to hold the first substrate group, the second substrate group, and the third substrate group aligned at the reference pitch while moving them by ⅓ pitch. Thus, a plurality of substrates W aligned at a ⅓ pitch in a face-to-back manner are once held by the pusher member 81.

Then, the holding groove switching drive unit 71 of the orientation changing unit 19 switches to the state in which the plurality of pairs of ⅔ pitch holding grooves 65A and 65B are usable. As a result, the orientation changing unit 19 can extract two or more first substrates W11 out of the plurality of substrates W in which two or more first substrates W11 and two or more second substrates W12 are alternately disposed from the plurality of substrates W held by the pusher member 81. Thereafter, the pusher mechanism 21 rotates the two or more second substrates W12 remaining on the pusher member 81 by 180 degrees about the vertical axis AX7. Thereafter, the two or more first substrates W11 extracted by the orientation changing unit 19 are returned to the pusher member 81. With this operation, a plurality of substrates W aligned at a ⅓ pitch in a face-to-face manner are held by the pusher member 81. Thus, a plurality of substrates can be easily aligned at a ⅓ pitch narrower than a half pitch in a face-to-face manner.

The holding groove switching drive unit 71 rotates the first vertical holding unit 39 about the rotation axis AX5 and rotates the second vertical holding unit 40 about the rotation axis AX6. With this operation, the holding groove switching drive unit 71 can switch between four states, that is, between a first state in which the plurality of pairs of reference pitch holding grooves 63A and 63B are usable, a second state in which the plurality of pairs of ⅔ pitch holding grooves 65A and 65B are usable, a third state in which the plurality of pairs of reference pitch holding grooves 67A and 67B are usable, and a fourth state in which the plurality of pairs of ⅔ pitch holding grooves 69A and 69B are usable.

The plurality of substrates W to be collectively processed are aligned at a pitch (in the present embodiment, ⅓ pitch) narrower than the half pitch. Thus, for example, the size of the batch processing tank BT1 for accommodating the plurality of substrates W can be reduced. As a result, the use amount of the processing liquid (chemical liquid and cleaning liquid) can be reduced.

### Second Embodiment

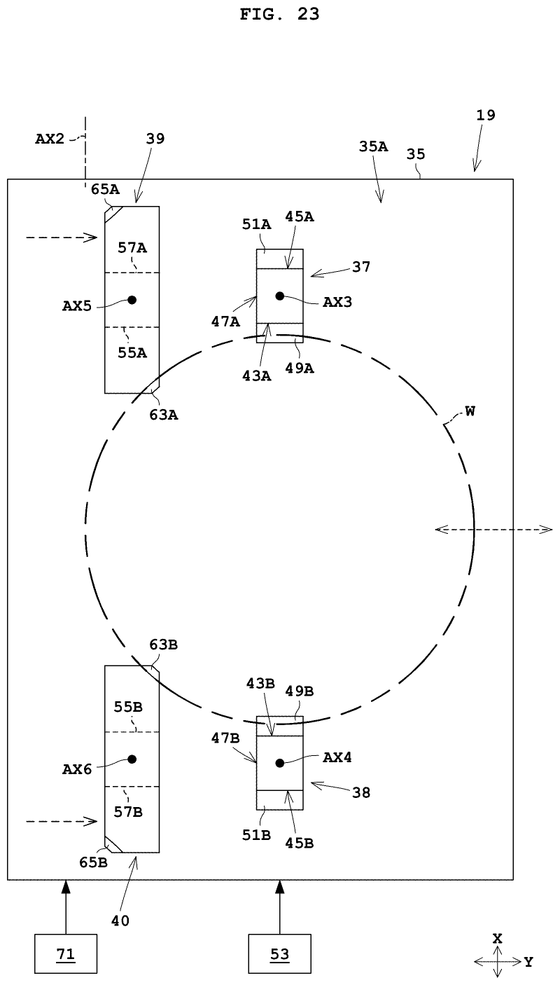

Hereinafter, a second embodiment of the present invention will be described with reference to the drawings. Descriptions overlapping with the first embodiment will be omitted. FIG. 23 is a plan view illustrating the orientation changing unit 19 according to the second embodiment.

In the first embodiment, the vertical holding units 39 and 40 include the reference pitch holding grooves 63A and 63B and the ⅔ pitch holding grooves 65A and 65B to handle the substrates W before processing. The vertical holding units 39 and 40 also include a plurality of pairs of reference pitch holding grooves 67A and 67B and a plurality of pairs of ⅔ pitch holding grooves 69A and 69B to handle the substrates W after processing. The four states were switched with this configuration.

In this regard, for example, when the substrate W before processing and the substrate W after processing are not distinguished, the vertical holding units 39 and 40 do not have to include the plurality of pairs of reference pitch holding grooves 67A and 67B and the plurality of pairs of ⅔ pitch holding grooves 69A and 69B.

See FIG. 23. The vertical holding units 39 and 40 do not include the plurality of pairs of reference pitch holding grooves 67A and 67B and the plurality of pairs of ⅔ pitch holding grooves 69A and 69B, but include the plurality of pairs of reference pitch holding grooves 63A and 63B and the plurality of pairs of ⅔ pitch holding grooves 65A and 65B.

The holding groove switching drive unit 71 switches between the first state in which the plurality of pairs of reference pitch holding grooves 63A and 63B are usable and the second state in which the plurality of pairs of ⅔ pitch holding grooves 65A and 65B are usable. That is, the holding groove switching drive unit 71 may be configured to switch between two states.

The present invention is not limited to the embodiments described above, and can be modified as follows.
(1) In each embodiment described above, the substrate processing apparatus 1 collectively processes 50 substrates W. In this regard, the substrate processing apparatus 1 may collectively process 75 substrates W. In this case, a processing substrate group in which a total of 75 substrates W of three carriers C are collectively processed is formed. That is, the 75 substrates W are aligned in a face-to-face manner at a ⅓ pitch.

The processing substrate group is formed based on the flowcharts of FIGS. 10 and 11. The 25 substrates W1 of the first carrier C are used as the first substrate group. The 25 substrates W2 of the second carrier Care used as the second substrate group. The 25 substrates W3 of the third carrier C are used as the third substrate group.

For example, the pair of horizontal holding units 37 and 38 includes pairs of pre-processing shelves 49A and 49B and 25 pairs of post-processing shelves 51A and 51B. The pusher member 81 includes 75 or 76 vertical holding grooves 93.

The pair of vertical holding units 39 and 40 includes 25 pairs of reference pitch holding grooves 63A and 63B and 38 pairs of ⅔ pitch holding grooves 65A and 65B to handle the substrates W before processing. The pair of vertical holding units 39 and 40 includes 25 pairs of reference pitch holding grooves 67A and 67B and 38 pairs of ⅔ pitch holding grooves 69A and 69B to handle the substrates W after processing.
(2) In each embodiment described above, the substrate processing apparatus 1 collectively processes 50 substrates W. In this regard, the substrate processing apparatus 1 may collectively process 100 substrates W. In this case, a processing substrate group in which a total of 100 substrates W of four carriers C are collectively processed is formed. That is, the 100 substrates W are aligned in a face-to-face manner at a ⅓ pitch.

The processing substrate group is formed based on the flowcharts of FIGS. 10 and 11. The 25 substrates W1 of the first carrier C and the nine substrate W1 of the second carrier C (34 substrate W1) are used as the first substrate group. The remaining 16 substrates W2 of the second carrier C and the 17 substrate W2 of the third carrier C (33 substrate W2) are used as the second substrate group. The remaining eight substrates W3 of the third carrier C and the 25 substrate W3 of the fourth carrier C (33 substrate W3) are used as the third substrate group.

For example, the pair of horizontal holding units 37 and 38 includes 34 pairs of pre-processing shelves 49A and 49B and 34 pairs of post-processing shelves 51A and 51B. The pusher member 81 includes 100 vertical holding grooves 93.

The pair of vertical holding units 39 and 40 includes 34 pairs of reference pitch holding grooves 63A and 63B and 50 pairs of ⅔ pitch holding grooves 65A and 65B to handle the substrates W before processing. The pair of vertical holding units 39 and 40 includes 34 pairs of reference pitch holding grooves 67A and 67B and 50 pairs of ⅔ pitch holding grooves 69A and 69B to handle the substrates W after processing.
(3) In each embodiment and modification described above, the holding groove switching drive unit 71 of the orientation changing unit 19 rotates the first vertical holding unit 39 about the rotation axis AX5 and rotates the second vertical holding unit 40 about the rotation axis AX6. With this operation, for example, the holding groove switching drive unit 71 switches from the first state in which the plurality of pairs of reference pitch holding grooves 63A and 63B are usable to the second state in which the plurality of pairs of ⅔ pitch holding grooves 65A and 65B are usable. This switching may be performed not by the rotation of each of the vertical holding units 39 and 40 but, for example, by horizontal movement.

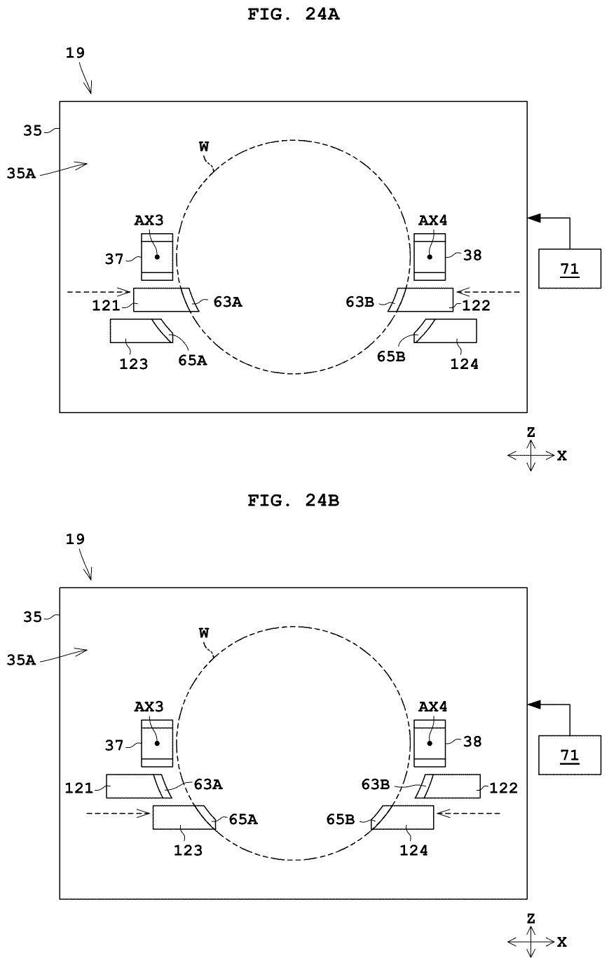

For example, as illustrated in FIGS. 24A and 24B, the orientation changing unit 19 includes two pairs of vertical holding units 121, 122, 123, and 124. The pair of vertical holding units 121 and 122 includes, for example, 17 pairs of reference pitch holding grooves 63A and 63B. The other pair of vertical holding units 123 and 124 includes, for example, 25 pairs of ⅔ pitch holding grooves 65A and 65B. The pair of vertical holding units 121 and 122 can move in the front-back directions X. The other pair of vertical holding units 123 and 124 can also move in the front-back directions X.

The holding groove switching drive unit 71 includes, for example, an electric actuator or an air cylinder. As illustrated in FIG. 24A, the holding groove switching drive unit 71 moves the pair of vertical holding units 121 and 122 close to each other. This allows the pair of vertical holding units 121 and 122 to hold the 17 substrates W in a vertical orientation aligned at the reference pitch. As illustrated in FIG. 24B, the holding groove switching drive unit 71 moves the other pair of vertical holding units 123 and 124 close to each other. This allows the other pair of vertical holding units 123 and 124 to hold the 25 substrates W aligned at the ⅔ pitch.
(4) In each embodiment and modification described above, the delivery mechanism 23 conveys, for example, 50 substrates W between the pusher mechanism 21 and the main conveyance mechanism WTR. That is, the delivery mechanism 23 conveys 50 substrates W from the pusher member 81 to the delivery position P for the delivery to the main conveyance mechanism WTR. In this regard, the pusher mechanism 21 may directly convey the 50 substrates W to the delivery position P. In this case, the delivery mechanism 23 does not have to be provided.
(5) In each embodiment and modification described above, the transfer block 5 includes one delivery mechanism 23. In this regard, the transfer block 5 may include a plurality of delivery mechanisms 23. For example, when two delivery mechanisms 23 are provided, a first delivery mechanism 23 may convey 50 substrates W from the pusher member 81 to the delivery position P for the delivery to the main conveyance mechanism WTR. A second delivery mechanism 23 may convey 50 substrates W to the pusher member 81 from another substrate delivery position for the delivery from the main conveyance mechanism WTR.
(6) In each embodiment and modification described above, the pusher member 81 holds a plurality of substrates W formed of the three substrate groups. The plurality of substrates W are aligned at a ⅓ pitch. In this regard, the plurality of substrates W (processing substrate group) to be collectively processed may be aligned at a ¼ pitch or a ⅕ pitch.

For example, when the plurality of substrates W are aligned at a ¼ pitch (for example, 2.5 mm pitch), the plurality of substrates W are formed by four substrate groups. Accordingly, the vertical holding units 39 and may include, instead of the ⅔ pitch holding grooves 65A and 65B (69A and 69B), a plurality of pairs of ½ pitch holding grooves aligned at a ½ pitch ( 2/4 pitch) (for example, 5 mm pitch) in the extending directions DR2. When the plurality of substrates W are aligned at a ⅕ pitch (for example, 2 mm pitch), the plurality of substrates W are formed by five substrate groups. Accordingly, the vertical holding units 39 and 40 may include, instead of the ⅔ pitch holding grooves 65A and 65B (69A and 69B), a plurality of pairs of ⅖ pitch holding grooves aligned at a ⅖ pitch (for example, 4 mm pitch) in the extending directions DR2.

That is, the plurality of substrates W to be collectively processed are aligned at a 1/N pitch. In this case, the plurality of substrates W are formed by N substrate groups. Accordingly, the vertical holding units 39 and 40 may include, instead of the ⅔ pitch holding grooves 65A and 65B (69A and 69B), a plurality of pairs of 2/N pitch holding grooves aligned at a 2/N pitch in the extending directions DR2. “N” in the 1/N pitch, the 2/N pitch, and N is a natural number of 3 or more.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate processing apparatus that collectively processes a plurality of substrates, the substrate processing apparatus comprising:
a substrate handling mechanism including a plurality of hands disposed in a vertical direction at a reference pitch, each of which holds 5 one substrate in a horizontal orientation;
an orientation changing unit that individually changes an orientation of N substrate groups each including two or more substrates aligned at the reference pitch from the horizontal orientation to a vertical orientation, wherein N is a natural number of three or more, the N substrate groups being sequentially received from the substrate handling mechanism; and
a pusher mechanism including a pusher member that holds the plurality of substrates aligned in the vertical orientation at a 1/N pitch that is 1/N times the reference pitch, the pusher mechanism forming the plurality of substrates on the pusher member by aligning the N substrate groups received from the orientation changing unit in one row with the pusher member while shifting the pusher member by the 1/N pitch in an alignment direction in which the plurality of substrates are aligned, wherein
the orientation changing unit includes:
a support base;
a pair of horizontal holding units that holds one substrate group of the N substrate groups in the horizontal orientation, the pair of horizontal holding units being provided in such a manner as to extend at a right angle with respect to a support surface of the support base;
a pair of vertical holding units including a plurality of pairs of reference pitch holding grooves and a plurality of pairs of 2/N pitch holding grooves, the pair of vertical holding units being provided in such a manner as to extend at the right angle with respect to the support surface of the support base;
a rotation drive unit that rotates the support base about a horizontal axis; and
a switching drive unit that switches between a state in which the plurality of pairs of reference pitch holding grooves are usable and a state in which the plurality of pairs of 2/N pitch holding grooves are usable,
the plurality of pairs of reference pitch holding grooves are disposed at the reference pitch in an extending direction in which the pair of vertical holding units extends,
the plurality of pairs of 2/N pitch holding grooves are disposed at a 2/N pitch that is 2/N times the reference pitch in the extending direction, and
the switching drive unit:
switches to the state in which the plurality of pairs of reference pitch holding grooves are usable when the plurality of substrates aligned in a face-to-back manner are formed in the pusher member; and
switches to the state in which the plurality of pairs of 2/N pitch holding grooves are usable when the plurality of substrates held by the pusher member are rearranged into a face-to-face manner.

2. The substrate processing apparatus according to claim 1, wherein
a first vertical holding unit of the pair of vertical holding unit is rotatable about a first rotation axis passing through the first vertical holding unit and extending at the right angle with respect to the support surface,
the first vertical holding unit includes a first outer peripheral surface and a second outer peripheral surface provided around the first rotation axis,
a second vertical holding unit of the pair of vertical holding unit is rotatable about a second rotation axis passing through the second vertical holding unit and extending at the right angle with respect to the support surface,
the second vertical holding unit includes a third outer peripheral surface and a fourth outer peripheral surface provided around the second rotation axis,
the first outer peripheral surface and the third outer peripheral surface are provided with the plurality of pairs of reference pitch holding grooves,
the second outer peripheral surface and the fourth outer peripheral surface are provided with the plurality of pairs of 2/N pitch holding grooves, and
the switching drive unit rotates the first vertical holding unit about the first rotation axis and rotates the second vertical holding unit about the second rotation axis to switch between the state in which the plurality of pairs of reference pitch holding grooves are usable and the state in which the plurality of pairs of 2/N pitch holding grooves are usable.

3. The substrate processing apparatus according to claim 2, wherein
the first vertical holding unit includes a fifth outer peripheral surface and a sixth outer peripheral surface provided around the first rotation axis in addition to the first outer peripheral surface and the second outer peripheral surface,
the second vertical holding unit includes a seventh outer peripheral surface and an eighth outer peripheral surface provided around the second rotation axis in addition to the third outer peripheral surface and the fourth outer peripheral surface,
the fifth outer peripheral surface and the seventh outer peripheral surface are provided with a plurality of pairs of post-processing reference pitch holding grooves disposed at the reference pitch in the extending direction,
the sixth outer peripheral surface and the eighth outer peripheral surface are provided with a plurality of pairs of post-processing 2/N pitch holding grooves disposed at the 2/N pitch in the extending direction,
the switching drive unit rotates the first vertical holding unit about the first rotation axis and rotates the second vertical holding unit about the second rotation axis to switch between the state in which the plurality of pairs of reference pitch holding grooves are usable, the state in which the plurality of pairs of 2/N pitch holding grooves are usable, a state in which the plurality of pairs of post-processing reference pitch holding grooves are usable, and a state in which the plurality of pairs of post-processing 2/N pitch holding grooves are usable, and
the switching drive unit:
switches to the state in which the plurality of pairs of post-processing 2/N pitch holding grooves are usable when the plurality of substrates held by the pusher member are rearranged into a face-to-back manner; and
switches to the state in which the plurality of pairs of post-processing reference pitch holding grooves are usable when the plurality of substrates held by the pusher member are divided into the N substrate groups.

4. The substrate processing apparatus according to claim 1,
the substrate processing apparatus comprising a controller, wherein
the controller:
causes the switching drive unit to switch to the state in which the plurality of pairs of reference pitch holding grooves are usable;
causes the orientation changing unit to sequentially receive the N substrate groups from the substrate handling mechanism;
causes the orientation changing unit to individually change the orientation of the N substrate groups from the horizontal orientation to the vertical orientation;
causes the pusher mechanism to hold the plurality of substrates aligned at the 1/N pitch in the face-to-back manner with the pusher member, the plurality of substrates being formed from the N substrate groups by the pusher member sequentially receiving the N substrate groups while the pusher member is shifted in the alignment direction by the 1/N pitch;
causes the switching drive unit to switch to the state in which the plurality of pairs of 2/N pitch holding grooves are usable;
causes the pair of vertical holding units to receive, from the pusher member, two or more first substrates aligned at the 2/N pitch among the plurality of substrates in which the two or more first substrates and two or more second substrates are alternately disposed;
causes the pusher mechanism to rotate the pusher member holding the two or more second substrates in the vertical orientation by 180 degrees about a vertical axis; and
causes the pusher member to receive the two or more first substrates from the pair of vertical holding units while alternately disposing the two or more first substrates and the two or more second substrates rotated by 180 degrees.

5. The substrate processing apparatus according to claim 1, the substrate processing apparatus further comprising:
a substrate processing unit that collectively processes the plurality of substrates aligned at the 1/N pitch in the face-to-face manner; and
a main conveyance mechanism that conveys the plurality of substrates aligned at the 1/N pitch in the face-to-face manner to the substrate processing unit.

6. The substrate processing apparatus according to claim 1, wherein
the N substrate groups are three substrate groups,
the 1/N pitch is a ⅓ pitch that is ⅓ times the reference pitch, and
the plurality of pairs of 2/N pitch holding grooves are a plurality of pairs of ⅔ pitch holding grooves disposed at a ⅔ pitch that is ⅔ times the reference pitch in the extending direction.

7. The substrate processing apparatus according to claim 3, wherein
the N substrate groups are three substrate groups,
the 1/N pitch is a ⅓ pitch that is ⅓ times the reference pitch,
the plurality of pairs of 2/N pitch holding grooves are a plurality of pairs of ⅔ pitch holding grooves disposed at a ⅔ pitch that is ⅔ times the reference pitch in the extending direction, and
the plurality of pairs of post-processing 2/N pitch holding grooves are a plurality of pairs of post-processing ⅔ pitch holding grooves disposed at the ⅔ pitch in the extending direction.
